(19) United States
(12) Patent Application Publication
(10) Pub. No.: US 2023/0246146 A1
(43) Pub. Date: Aug. 3, 2023

(54) DISPLAY DEVICE

(71) Applicant: Samsung Display Co., LTD., Yongin-si (KR)

(72) Inventors: Dong Hee SHIN, Asan-si (KR); Sun Kwun SON, Suwon-si (KR)

(73) Assignee: Samsung Display Co., LTD., Yongin-si (KR)

(21) Appl. No.: 17/949,358

(22) Filed: Sep. 21, 2022

(30) Foreign Application Priority Data
Jan. 28, 2022 (KR) 10-2022-0013454

(51) Int. Cl. H01L 33/62; H01L 33/38; H01L 25/075

(52) U.S. Cl. CPC H01L 33/62; H01L 33/382; H01L 25/0753

(57) ABSTRACT

A display device comprises a first voltage line included in a first metal layer on a substrate and extending in a first direction, a first transistor electrically connected to the first voltage line and comprising a source electrode included in an active layer on the first metal layer and a gate electrode included in a second metal layer on the active layer, and a first capacitor electrically connected between the gate electrode of the first transistor and the source electrode of the first transistor. The first capacitor comprises a first capacitor electrode included in the first metal layer and electrically connected to the gate electrode of the first transistor, and a second capacitor electrode included in the active layer. The second capacitor electrode and the source electrode of the first transistor are integrally formed with each other.

### CROSS-REFERENCE TO RELATED APPLICATION

This application claims priority to and benefits of Korean Patent Application No. 10-2022-0013454 under 35 U.S.C. § 119, filed in the Korean Intellectual Property Office on Jan. 28, 2022, the entire contents of which are incorporated herein by reference.

### BACKGROUND

### 1. Technical Field

The disclosure relates to a display device capable of preventing horizontal crosstalk to improve image quality.

### 2. Description of the Related Art

The importance of display devices for displaying images has been emphasized because of the increasing developments of information technology. The display devices have been applied to various electronic devices such as smartphones, digital cameras, notebook computers, navigation devices, and smart televisions. The display devices may be flat panel display devices such as liquid crystal display devices, field emission display devices, and organic light emitting display devices. Among these flat panel display devices, a light emitting display device includes light emitting elements, that emit light independently without a light emitting part. The light emitting element may be an organic light emitting diode using an organic material as a fluorescent material or an inorganic light emitting diode using an inorganic material as a fluorescent material.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a display device capable of preventing horizontal crosstalk to improve image quality.

However, embodiments of the disclosure are not limited to those set forth herein. The above and other embodiments will become more apparent to one of ordinary skill in the art to which the disclosure pertains by referencing the detailed description of the disclosure given below.

According to an embodiment of the disclosure, a display device comprises a first voltage line included in a first metal layer on a substrate and extending in a first direction, a first transistor electrically connected to the first voltage line and comprising a source electrode included in an active layer on the first metal layer and a gate electrode included in a second metal layer on the active layer, and a first capacitor electrically connected between the gate electrode of the first transistor and the source electrode of the first transistor. The first capacitor comprises a first capacitor electrode included in the first metal layer and electrically connected to the gate electrode of the first transistor, and a second capacitor electrode included in the active layer. The second capacitor electrode and the source electrode of the first transistor are integrally formed with each other.

The display device may further comprise a first connection electrode included in the second metal layer and electrically connecting the first voltage line and a drain electrode of the first transistor.

The display device may further comprise a second connection electrode included in the second metal layer. The second connection electrode and the gate electrode of the first transistor may be integrally formed with each other. The second connection electrode may be electrically connected to the first capacitor electrode.

The display device may further comprise a data line included in the first metal layer and extending in the first direction, and a second transistor electrically connecting the data line and the gate electrode of the first transistor.

The display device may further comprise a third connection electrode included in the second metal layer and electrically connecting the data line and a drain electrode of the second transistor.

The display device may further comprise a fourth connection electrode included in the second metal layer and electrically connecting the first capacitor electrode and a source electrode of the second transistor.

The display device may further comprise an initialization voltage line included in the first metal layer and extending in the first direction, and a third transistor electrically connecting the initialization voltage line and the source electrode of the first transistor.

A drain electrode of the third transistor and the second capacitor electrode may be integral with each other.

The display device may further comprise an active extension portion extending from the second capacitor electrode, a first electrode included in a third metal layer on the second metal layer, extending in the first direction, and electrically connected to the active extension portion, and a second electrode extending parallel to the first electrode included in the third metal layer.

The display device may further comprise a light emitting element, a second voltage line included in the second metal layer and extending in a second direction intersecting the first direction, a first contact electrode included in a fourth metal layer on the third metal layer and electrically connecting the first electrode and the light emitting element, and a second contact electrode included in the fourth metal layer and electrically connecting the light emitting element and the second voltage line.

The display device may further comprise a horizontal voltage line included in the second metal layer, extending in a second direction intersecting the first direction, and electrically connected to the first voltage line, a first electrode included in a third metal layer on the second metal layer, extending in the first direction, and electrically connected to the horizontal voltage line, and a second electrode extending parallel to the first electrode included in the third metal layer.

The display device may further comprise an active extension portion extending from the second capacitor electrode, and a first contact electrode included in a fourth metal layer on the third metal layer and directly connected to the active extension portion.

The display device may further comprise a light emitting element, a second voltage line included in the second metal layer and extending in the second direction intersecting the first direction, and a second contact electrode included in the fourth metal layer and electrically connecting the light emitting element and the second voltage line.

The display device may further comprise a vertical gate line included in the first metal layer and extending in the first direction, a horizontal gate line included in the second metal layer and extending in the second direction, and an auxiliary gate line extending from the horizontal gate line in the first direction.

According to an embodiment of the disclosure, a display device comprises a substrate, a first metal layer on the substrate, an active layer on the first metal layer, a second metal layer on the active layer, a first transistor included in the active layer and the second metal layer, and a first capacitor electrically connected between a gate electrode of the first transistor and a source electrode of the first transistor. The first capacitor comprises a first capacitor electrode included in the first metal layer and electrically connected to the gate electrode of the first transistor, and a second capacitor electrode included in the active layer. The second capacitor electrode and the source electrode of the first transistor are integrally formed with each other.

The display device may further comprise an active extension portion extending from the second capacitor electrode, a first electrode included in a third metal layer on the second metal layer, extending in the first direction, and electrically connected to the active extension portion, and a second electrode extending parallel to the first electrode included in the third metal layer.

The display device may further comprise a light emitting element, a second voltage line included in the second metal layer and extending in a second direction intersecting the first direction, a first contact electrode included in a fourth metal layer on the third metal layer and electrically connecting the first electrode and the light emitting element, and a second contact electrode included in the fourth metal layer and electrically connecting the light emitting element and the second voltage line.

The display device may further comprise a horizontal voltage line included in the second metal layer, extending in a second direction intersecting the first direction, and electrically connected to the first voltage line, a first electrode included in a third metal layer on the second metal layer, extending in the first direction, and electrically connected to the horizontal voltage line, and a second electrode extending parallel to the first electrode included in the third metal layer.

The display device may further comprise an active extension portion extending from the second capacitor electrode, and a first contact electrode included in a fourth metal layer on the third metal layer and directly connected to the active extension portion.

The display device may further comprise a light emitting element, a second voltage line included in the second metal layer and extending in the second direction intersecting the first direction, and a second contact electrode included in the fourth metal layer and electrically connecting the light emitting element and the second voltage line.

### BRIEF DESCRIPTION OF THE DRAWINGS

An additional appreciation according to the embodiments of the disclosure will become apparent by describing in detail the embodiments thereof with reference to the accompanying drawings, wherein:

FIG. 1 is a schematic plan view of a display device according to an embodiment;

FIG. 2 is a schematic plan view illustrating contact portions of vertical gate lines and horizontal gate lines in the display device according to the embodiment;

FIG. 3 schematically illustrates pixels and lines of the display device according to the embodiment;

FIG. 4 is a schematic diagram of an equivalent circuit of a pixel of the display device according to the embodiment;

FIGS. 5 and 6 are schematic plan views of a portion of a display area in the display device according to the embodiment;

FIG. 7 is a schematic cross-sectional view taken along line I-I′ of FIGS. 5 and 6;

FIG. 8 is a schematic cross-sectional view taken along line II-IF of FIGS. 5 and 6;

FIG. 9 is a schematic plan view illustrating a first metal layer, an active layer, a second metal layer, and a third metal layer in the display device according to the embodiment;

FIG. 10 is a schematic plan view illustrating the first metal layer, the active layer, the second metal layer, the third metal layer, and a fourth metal layer in the display device according to the embodiment;

FIG. 11 is a schematic plan view illustrating the third metal layer, light emitting elements, and the fourth metal layer in the display device according to the embodiment;

FIG. 12 is a schematic cross-sectional view taken along lines and IV-IV′ of FIGS. 10 and 11;

FIG. 13 is a schematic plan view illustrating a first metal layer, an active layer, a second metal layer, and a third metal layer in a display device according to an embodiment;

FIG. 14 is a schematic plan view illustrating the first metal layer, the active layer, the second metal layer, the third metal layer, and a fourth metal layer in the display device according to the embodiment of FIG. 13;

FIG. 15 is a schematic plan view illustrating the third metal layer, light emitting elements, and the fourth metal layer in the display device according to the embodiment of FIG. 13; and

FIG. 16 is a schematic cross-sectional view taken along lines V-V′ and VI-VI′ of FIGS. 14 and 15.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. For example, well-known structures and devices are shown in block diagram form in order to avoid unnecessarily obscuring various embodiments. Here, various embodiments do not have to be exclusive not limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

The phrase “at least one of” is intended to include the meaning of “at least one selected from the group of” for the purpose of its meaning and interpretation. For example, “at least one of A and B” may be understood to mean “A, B, or A and B.”

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or overly formal sense, unless clearly so defined herein.

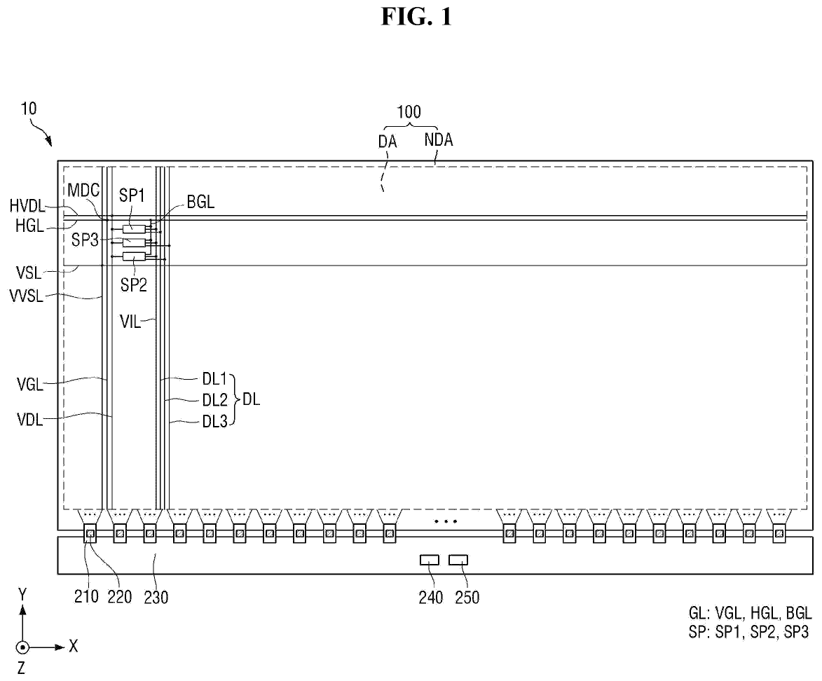

FIG. 1 is a schematic plan view of a display device according to an embodiment.

In the specification, “above,” “top” and “upper surface” refer to an upward direction (e.g., a Z-axis direction) of the display device 10, and “below,” “bottom” and “lower surface” refer to a downward direction (e.g., a direction opposite to the Z-axis direction) of the display device 10. Also, “left,” “right,” “up,” and “down” refer to directions when the display device 10 is seen in a plan view. For example, “left” refers to a direction opposite to an X-axis direction, “right” refers to the X-axis direction, “up” refers to a Y-axis direction, and “down” refers to a direction opposite to the Y-axis direction.

Referring to FIG. 1, the display device 10 may be a device for displaying moving images or still images. The display device 10 may be used as a display screen in portable electronic devices such as mobile phones, smartphones, tablet personal computers (PCs), smart watches, watch phones, mobile communication terminals, electronic notebooks, electronic books, portable multimedia players (PMI's), navigation devices, ultra-mobile PCs (UMPCs), or the like. For example, the display device 10 may be used as a display screen in various products such as televisions, notebook computers, monitors, billboards, Internet of things (IoT) devices, or the like.

The display device 10 may include a display panel 100, flexible films 210, display drivers 220, a circuit board 230, a timing controller 240, and a power supply part 250.

The display panel 100 may be rectangular in a plan view. For example, the display panel 100 may have a rectangular planar shape having long sides in a first direction (e.g., X-axis direction) and short sides in a second direction (e.g., Y-axis direction). Each corner where the long side extending in the first direction (e.g., X-axis direction) meets the short side extending in the second direction (e.g., Y-axis direction) may be right-angled or rounded with a curvature (e.g., a predetermined or selectable curvature). The order of the directions of the specification may be different from those in the specification. For example, the first direction of the specification may be a second direction in claims, and the second direction of the specification may be a first direction in the claims. The planar shape of the display panel 100 is not limited to the rectangular shape but may also be various polygonal shapes, a circular shape, an oval shape, or the like. For example, the display panel 100 may be flat, but the disclosure is not limited thereto. For another example, the display panel 100 may be curved with a curvature.

The display panel 100 may include a display area DA and a non-display area NDA.

The display area DA may be an area for displaying an image and may be defined as a central area of the display panel 100. The display area DA may include pixels SP, gate lines GL, data lines DL, initialization voltage lines VIL, first voltage lines VDL, horizontal voltage lines HVDL, vertical voltage lines VVSL, and second voltage lines VSL. The pixels SP may be formed in each of pixel areas intersected by the data lines DL and the gate lines GL. The pixels SP may include first to third pixels SP1 to SP3. Each of the first to third pixels SP1 to SP3 may be connected to a horizontal gate line HGL and a data line DL. Each of the first to third pixels SP1 to SP3 may be defined as a minimum area that outputs light.

The first pixels SP1 may emit light of a first color or red light. The second pixels SP2 may emit light of a second color or green light. The third pixels SP3 may emit light of a third color or blue light. Pixel circuits of the first pixels SP1, pixel circuits of the third pixels SP3, and pixel circuits of the second pixels SP2 may be arranged in a direction opposite to the second direction (e.g., Y-axis direction), but the order of the pixel circuits is not limited thereto.

The gate lines GL may include vertical gate lines VGL, the horizontal gate lines HGL, and auxiliary gate lines BGL.

The vertical gate lines VGL may be connected to the display drivers 220. The vertical gate lines VGL may extend in the second direction (e.g., Y-axis direction) and may be spaced apart from each other in the first direction (e.g., X-axis direction). The vertical gate lines VGL may be disposed parallel to the data lines DL. The horizontal gate lines HGL may extend in the first direction (e.g., X-axis direction) and may be spaced apart from each other in the second direction (e.g., Y-axis direction). Each of the horizontal gate lines HGL may intersect (e.g., cross) the vertical gate lines VGL. For example, a horizontal gate line HGL may be connected to a vertical gate line VGL through a contact portion MDC. The contact portion MDC may be a portion in which the horizontal gate line HGL is inserted into a contact hole to contact the vertical gate line VGL. For example, the horizontal gate line HGL may be connected to the vertical gate line VGL through the contact portion MDC. The auxiliary gate lines BGL may extend from each of the horizontal gate lines HGL, and supply a gate signal to the first to third pixels SP1 to SP3.

The data lines DL may extend in the second direction (e.g., Y-axis direction) and may be spaced apart from each other in the first direction (e.g., X-axis direction). The data lines DL may include first to third data lines DL1 to DL3. The first to third data lines DL1 to DL3 may supply data voltages to the first to third pixels SP1 to SP3, respectively.

The initialization voltage lines VIL may extend in the second direction (e.g., Y-axis direction) and may be spaced apart from each other in the first direction (e.g., X-axis direction). Each of the initialization voltage lines VIL may supply an initialization voltage received from a display driver 220 to the pixel circuit of each of the first to third pixels SP1 to SP3. Each of the initialization voltage lines VIL may receive a sensing signal from the pixel circuit of each of the first to third pixels SP1 to SP3 and may supply the sensing signal to the display driver 220.

The first voltage lines VDL may extend in the second direction (e.g., Y-axis direction) and may be spaced apart from each other in the first direction (e.g., X-axis direction). The first voltage lines VDL may supply a driving voltage or a high potential voltage received from the power supply part 250 to the first to third pixels SP1 to SP3.

The horizontal voltage lines HVDL may extend in the first direction (e.g., X-axis direction) and may be spaced apart from each other in the second direction (e.g., Y-axis direction). The horizontal voltage lines HVDL may be connected to the first voltage lines VDL. The horizontal voltage lines HVDL may receive a driving voltage or a high potential voltage from the first voltage lines VDL.

The vertical voltage lines VVSL may extend in the second direction (e.g., Y-axis direction) and may be spaced apart from each other in the first direction (e.g., X-axis direction). The vertical voltage lines VVSL may be connected to the second voltage lines VSL. The vertical voltage lines VVSL may supply a low potential voltage received from the power supply part 250 to the second voltage lines VSL.

The second voltage lines VSL may extend in the first direction (e.g., X-axis direction) and may be spaced apart from each other in the second direction (e.g., Y-axis direction). The second voltage lines VSL may supply a low potential voltage to the first to third pixels SP1 to SP3.

The connection relationship between the pixels SP, the gate lines GL, the data lines DL, the initialization voltage lines VIL, the first voltage lines VDL, and the second voltage lines VSL may be designed and changed according to the number and arrangement of the pixels SP.

The non-display area NDA may be defined as an area other than the display area DA in the display panel 100. For example, the non-display area NDA may include fan-out lines connecting the vertical gate lines VGL, the data lines DL, the initialization voltage lines VIL, the first voltage lines VDL, and the vertical voltage lines VVSL to the display drivers 220 and a pad part (not illustrated) connected to the flexible films 210.

Input terminals provided on a side of each of the flexible films 210 may be attached to the circuit board 230 by a film attaching process. Output terminals provided on another side of each of the flexible films 210 may be attached to the pad part by a film attaching process. For example, each of the flexible films 210 may be a flexible film that may be bent, such as a tape carrier package or a chip on film. The flexible films 210 may be bent toward a bottom of the display panel 100 and reduce a bezel area of the display device 10.

The display drivers 220 may be mounted on the flexible films 210. For example, the display drivers 220 may be implemented as integrated circuits. The display drivers 220 may receive digital video data and a data control signal from the timing controller 240, convert the digital video data into analog data voltages according to the data control signal, and transmit the analog data voltages to the data lines DL through the fan-out lines. The display drivers 220 may generate gate signals according to a gate control signal received from the timing controller 240 and sequentially supply the gate signals to the vertical gate lines VGL according to a set order. Accordingly, each of the display drivers 220 may simultaneously serve as a data driver and a gate driver. The display device 10 including the display drivers 220 disposed on a lower side of the non-display area NDA may minimize sizes of left, right, and upper sides of the non-display area NDA.

The circuit board 230 may support the timing controller 240 and the power supply part 250 and supply signals and power to the display drivers 220. For example, the circuit board 230 may supply a signal received from the timing controller 240 and a power supply voltage received from the power supply part 250 to the display drivers 220 to display an image in each pixel. Signal lines and power lines may be provided on the circuit board 230 and supply the signals and the power.

The timing controller 240 may be mounted on the circuit board 230 and may receive image data and a timing synchronization signal from a display driving system or a graphics device through a user connector provided on the circuit board 230. The timing controller 240 may align the image data suitable for a pixel arrangement structure based on the timing synchronization signal and generate digital video data. The timing controller 240 may supply the generated digital video data to the display drivers 220. The timing controller 240 may generate a data control signal and a gate control signal based on the timing synchronization signal. The timing controller 240 may control the supply timing of the data voltages of the display drivers 220 based on the data control signal. The timing controller 240 may control the supply timing of the gate signals of the display drivers 220 based on the gate control signal.

The power supply part 250 may be disposed on the circuit board 230, and supply a power supply voltage to the display drivers 220 and the display panel 100. For example, the power supply part 250 may generate a driving voltage or a high potential voltage, and supply the driving voltage or the high potential voltage to the first voltage lines VDL. The power supply part 250 may generate a low potential voltage and supply the low potential voltage to the vertical voltage lines VVSL. The power supply part 250 may generate an initialization voltage and supply the initialization voltage to the initialization voltage lines VIL.

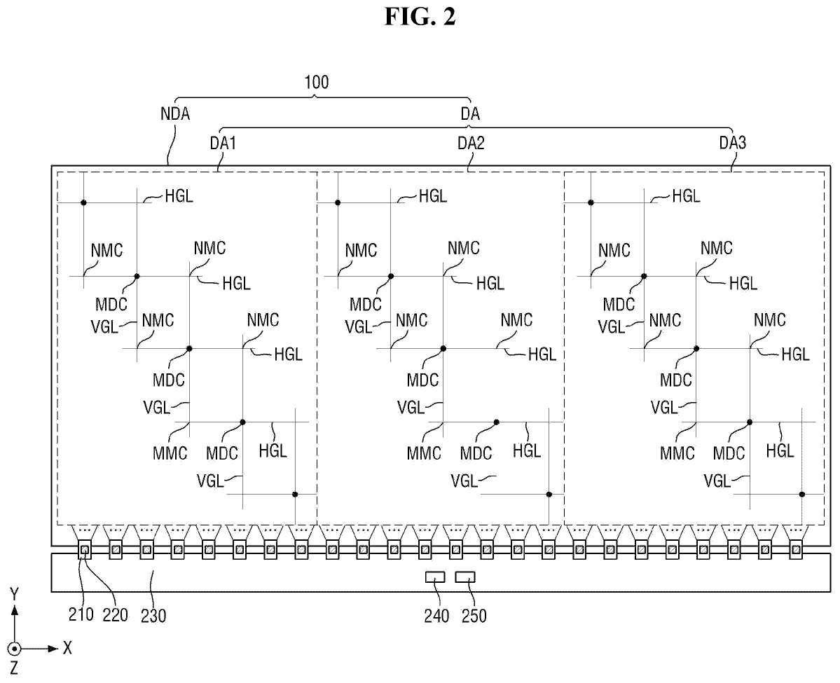

FIG. 2 is a schematic plan view illustrating the contact portions of the vertical gate lines and the horizontal gate lines in the display device according to the embodiment.

Referring to FIG. 2, the display area DA may include first to third display areas DA1 to DA3.

Each of the horizontal gate lines HGL may intersect (e.g., cross) the vertical gate lines VGL. Each of the horizontal gate lines HGL may intersect (e.g., cross) the vertical gate lines VGL in the contact portions MDC and non-contact portions NMC. For example, a horizontal gate line HGL may be connected to a vertical gate line VGL through a contact portion MDC. A horizontal gate line HGL may be insulated (e.g., electrically insulated) from another vertical gate lines VGL in the non-contact portions NMC.

The contact portions MDC of the first display area DA1 may be disposed on an extension line extending from an upper left corner of the first display area DA1 to a lower right corner of the first display area DA1. The contact portions MDC of the second display area DA2 may be disposed on an extension line extending from an upper left corner of the second display area DA2 to a lower right corner of the second display area DA2. The contact portions MDC of the third display area DA3 may be disposed on an extension line extending from an upper left corner of the third display area DA3 to a lower right corner of the third display area DA3. Therefore, the contact portions MDC may be arranged along a diagonal direction between the first direction (e.g., X-axis direction) and the direction opposite to the second direction (e.g., Y-axis direction) in each of the first to third display areas DA1 to DA3.

The display device 10 may include the display drivers 220, and each of the display drivers 220 may serve as a data driver and a gate driver. Therefore, the data lines DL may receive the data voltages from the display drivers 220 disposed on the lower side of the non-display area NDA, and the vertical gate lines VGL may receive the gate signals from the display drivers 220 disposed on the lower side of the non-display area NDA. Accordingly, the sizes of the left, right, and upper sides of the non-display area NDA of the display device 10 may be minimized.

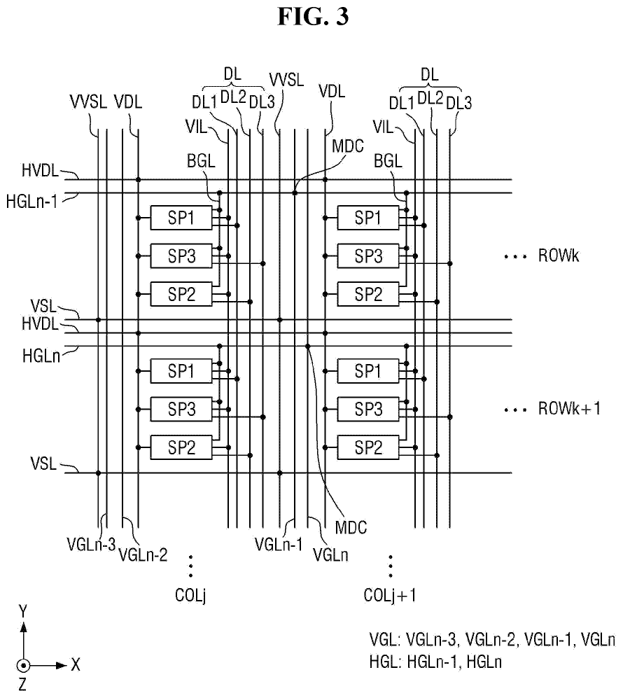

FIG. 3 schematically illustrates pixels and lines of the display device according to the embodiment.

Referring to FIG. 3, the pixels SP may include the first to third pixels SP1 to SP3. The pixel circuits of the first pixels SP1, the pixel circuits of the third pixels SP3, and the pixel circuits of the second pixels SP2 may be arranged in the direction opposite to the second direction (e.g., Y-axis direction), but the order of the pixel circuits is not limited thereto.

Each of the first to third pixels SP1 to SP3 may be connected to a first voltage line VDL, an initialization voltage line VIL, a gate line GL, and a data line DL.

The first voltage lines VDL may extend in the second direction (e.g., Y-axis direction). Each of the first voltage lines VDL may be disposed on a left side of the pixel circuits of the first to third pixels SP1 to SP3. Each of the first voltage lines VDL may supply a driving voltage or a high potential voltage to a transistor of each of the first to third pixels SP1 to SP3.

The horizontal voltage lines HVDL may extend in the first direction (e.g., X-axis direction). The horizontal voltage lines HVDL may be disposed above the horizontal gate lines HGL. The horizontal voltage lines HVDL may be connected to the first voltage lines VDL. The horizontal voltage lines HVDL may receive a driving voltage or a high potential voltage from the first voltage lines VDL.

The initialization voltage lines VIL may extend in the second direction (e.g., Y-axis direction). Each of the initialization voltage lines VIL may be disposed on a right side of the auxiliary gate lines BGL. Each of the initialization voltage lines VIL may be disposed between the auxiliary gate lines BGL and a data line DL. Each of the initialization voltage lines VIL may supply an initialization voltage to the pixel circuit of each of the first to third pixels SP1 to SP3. Each of the initialization voltage lines VIL may receive a sensing signal from the pixel circuit of each of the first to third pixels SP1 to SP3 and may supply the sensing signal to a display driver 220.

The gate lines GL may include the vertical gate lines VGL, the horizontal gate lines HGL, and the auxiliary gate lines BGL.

The vertical gate lines VGL may extend in the second direction (e.g., Y-axis direction). At least one vertical gate line VGL may be disposed between adjacent pixels SP. The vertical gate lines VGL may be connected between the display drivers 220 and the horizontal gate lines HGL. Each of the vertical gate lines VGL may intersect (e.g., cross) the horizontal gate lines HGL. Each of the vertical gate lines VGL may supply a gate signal received from a display driver 220 to a horizontal gate line HGL.

For example, an (n−3)^{th} vertical gate line VGLn−3 (where n is a positive integer) and an (n−2)^{th} vertical gate line VGLn−2 may be disposed on a left side of the pixels SP disposed in a j^{th} column COLj (where j is a positive integer). The vertical gate lines VGL may be disposed on a left side of each first voltage line VDL and may extend parallel to the first voltage line VDL. An (n−1)^{th} vertical gate line VGLn−1 and an n^{th} vertical gate line VGLn may be disposed between the data lines DL connected to the pixel SP disposed in the j^{th} column COLj and a first voltage line VDL connected to the pixels SP disposed in a (j+1)^{th} column COLj+1. The (n−1)^{th} vertical gate line VGLn−1 may be connected to an (n−1)^{th} horizontal gate line HGLn−1 through a contact portion MDC and may be insulated (e.g., electrically insulated) from another horizontal gate lines HGL. The n^{th} vertical gate line VGLn may be connected to an n^{th} horizontal gate line HGLn through a contact portion MDC and may be insulated from another horizontal gate lines HGL. The (n−1)^{th} and n^{th} vertical gate lines VGLn−1 and VGLn may be disposed on a left side of the first voltage line VDL connected to the pixel SP disposed in the (j+1)^{th} column COLj+1.

The horizontal gate lines HGL may extend in the first direction (e.g., X-axis direction). The horizontal gate lines HGL may be disposed above the pixel circuits of the first pixels SP1. The horizontal gate lines HGL may be connected between the vertical gate lines VGL and the auxiliary gate lines BGL. Each of the horizontal gate lines HGL may supply a gate signal received from a vertical gate line VGL to the auxiliary gate lines BGL.

For example, the (n−1)^{th} horizontal gate line HGLn−1 may be disposed above the pixel circuits of the first pixels SP1 disposed in a k^{th} row ROWk (where k is a positive integer). The (n−1)^{th} horizontal gate line HGLn−1 may be connected to the (n−1)^{th} vertical gate line VGLn−1 through a contact portion MDC and may be insulated from another vertical gate lines VGL. The n^{th} horizontal gate line HGLn may be disposed above the pixel circuits of the first pixels SP1 disposed in a (k+1)^{th} row ROWk+1. The n^{th} horizontal gate line HGLn may be connected to the n^{th} vertical gate line VGLn through a contact portion MDC and may be insulated from another vertical gate lines VGL.

The auxiliary gate lines BGL may extend from each of the horizontal gate lines HGL in the direction opposite to the second direction (e.g., Y-axis direction). Each of the auxiliary gate lines BGL may be disposed on a right side of the pixel circuits of the first to third pixels SP1 to SP3. Each of the auxiliary gate lines BGL may supply a gate signal received from a horizontal gate line HGL to the pixel circuits of the first to third pixels SP1 to SP3.

The data lines DL may extend in the second direction (the Y-axis direction). The data lines DL may supply data voltages to the pixels SP. The data lines DL may include first to third data lines DL1 to DL3.

The first data lines DL1 may extend in the second direction (e.g., Y-axis direction). Each of the first data lines DL1 may be disposed on a right side of an initialization voltage line VIL. Each of the first data lines DL1 may supply a data voltage received from a display driver 220 to the pixel circuits of the first pixels SP1.

The second data lines DL2 may extend in the second direction (e.g., Y-axis direction). Each of the second data lines DL2 may be disposed on a right side of a first data line DL1. Each of the second data lines DL2 may supply a data voltage received from a display driver 220 to the pixel circuits of the second pixels SP2.

The third data lines DL3 may extend in the second direction (e.g., Y-axis direction). Each of the third data lines DL3 may be disposed on a right side of a second data line DL2. Each of the third data lines DL3 may supply a data voltage received from a display driver 220 to the pixel circuits of the third pixels SP3.

The vertical voltage lines VVSL may extend in the second direction (e.g., Y-axis direction). Each of the vertical voltage lines VVSL may be disposed on a left side of a vertical gate line VGL. The vertical voltage lines VVSL may be connected between the power supply part 250 and the second voltage lines VSL. Each of the vertical voltage lines VVSL may supply a low potential voltage received from the power supply part 250 to the second voltage lines VSL.

The second voltage lines VSL may extend in the first direction (e.g., X-axis direction). The second voltage lines VSL may be disposed below the pixel circuits of the second pixels SP2. Each of the second voltage lines VSL may supply a low potential voltage received from the vertical voltage lines VVSL to light emitting element layers of the first to third pixels SP1 to SP3.

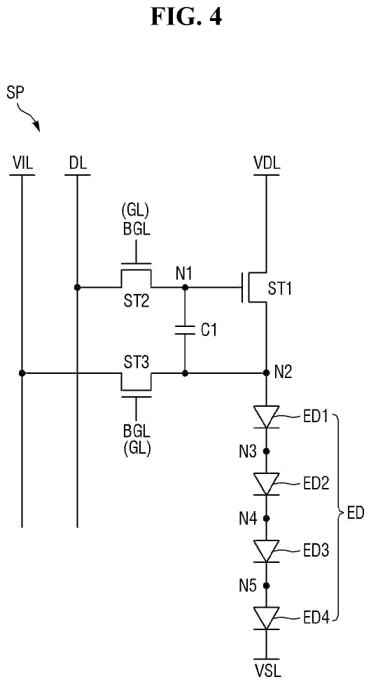

FIG. 4 is a schematic diagram of an equivalent circuit of a pixel of the display device according to the embodiment.

Referring to FIG. 4, each of the pixels SP may be connected to a first voltage line VDL, a data line DL, an initialization voltage line VIL, a gate line GL, and a second voltage line VSL.

Each of the first to third pixels SP1 to SP3 may include first to third transistors ST1 to ST3, a first capacitor C1, and light emitting elements ED.

The first transistor ST1 may include a gate electrode, a drain electrode, and a source electrode. The gate electrode of the first transistor ST1 may be connected to a first node N1. The drain electrode of the first transistor ST1 may be connected to the first voltage line VDL. The source electrode of the first transistor ST1 may be connected to a second node N2. The first transistor ST1 may control a drain-source current (or a driving current) based on a data voltage applied to the gate electrode.

The light emitting elements ED may include first to fourth light emitting elements ED1 to ED4. The first to fourth light emitting elements ED1 to ED4 may be connected in series. The first to fourth light emitting elements ED1 to ED4 may receive a driving current to emit light. The amount of light emitted from each light emitting element ED or the luminance of each light emitting element ED may be proportional to the magnitude of the driving current. Each of the light emitting elements ED may be, but is not limited to, an inorganic light emitting element including an inorganic semiconductor.

A first electrode of the first light emitting element ED1 may be connected to a second node N2, and a second electrode of the first light emitting element ED1 may be connected to a third node N3. The first electrode of the first light emitting element ED1 may be connected to the source electrode of the first transistor ST1, a drain electrode of the third transistor ST3, and a second capacitor electrode of the first capacitor C1 through the second node N2. The second electrode of the first light emitting element ED1 may be connected to a first electrode of the second light emitting element ED2 through the third node N3.

The first electrode of the second light emitting element ED2 may be connected to the third node N3, and a second electrode of the second light emitting element ED2 may be connected to a fourth node N4. A first electrode of the third light emitting element ED3 may be connected to the fourth node N4, and a second electrode of the third light emitting element ED3 may be connected to a fifth node N5. A first electrode of the fourth light emitting element ED4 may be connected to the fifth node N5, and a second electrode of the fourth light emitting element ED4 may be connected to the second voltage line VSL.

The second transistor ST2 may be turned on by a gate signal of the gate line GL and electrically connect the data line DL and the first node N1 that is the gate electrode of the first transistor ST1. The second transistor ST2 may be turned on based on the gate signal and supply a data voltage to the first node N1. The second transistor ST2 may have a gate electrode connected to the gate line GL, a drain electrode connected to the data line DL, and a source electrode connected to the first node N1. The source electrode of the second transistor ST2 may be connected to the gate electrode of the first transistor ST1 and a first capacitor electrode of the first capacitor C1 through the first node N1.

The third transistor ST3 may be turned on by the gate signal of the gate line GL and electrically connect the initialization voltage line VIL and the second node N2 that is the source electrode of the first transistor ST1. The third transistor ST3 may be turned on based on the gate signal and supply an initialization voltage to the second node N2. The third transistor ST3 may be turned on based on the gate signal and supply a sensing signal to the initialization voltage line VIL. The third transistor ST3 may have a gate electrode connected to the gate line GL, the drain electrode connected to the second node N2, and a source electrode connected to the initialization voltage line VIL. The drain electrode of the third transistor ST3 may be connected to the source electrode of the first transistor ST1, the second capacitor electrode of the first capacitor C1, and the first electrode of the first light emitting element ED1 through the second node N2.

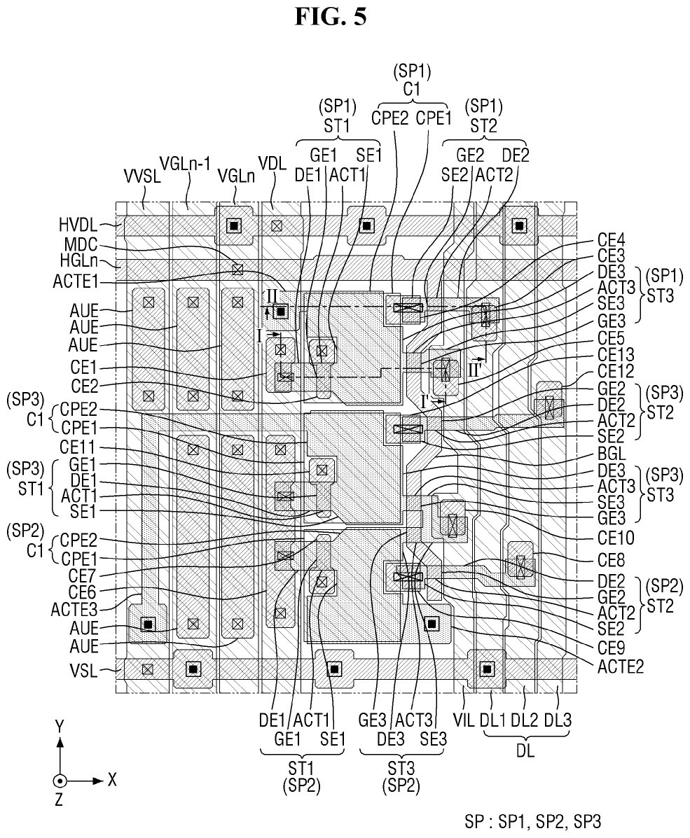

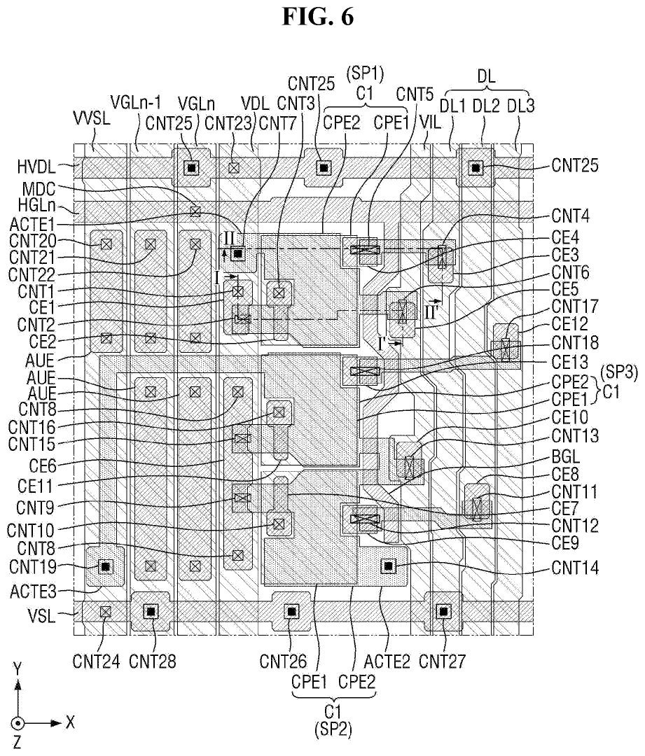

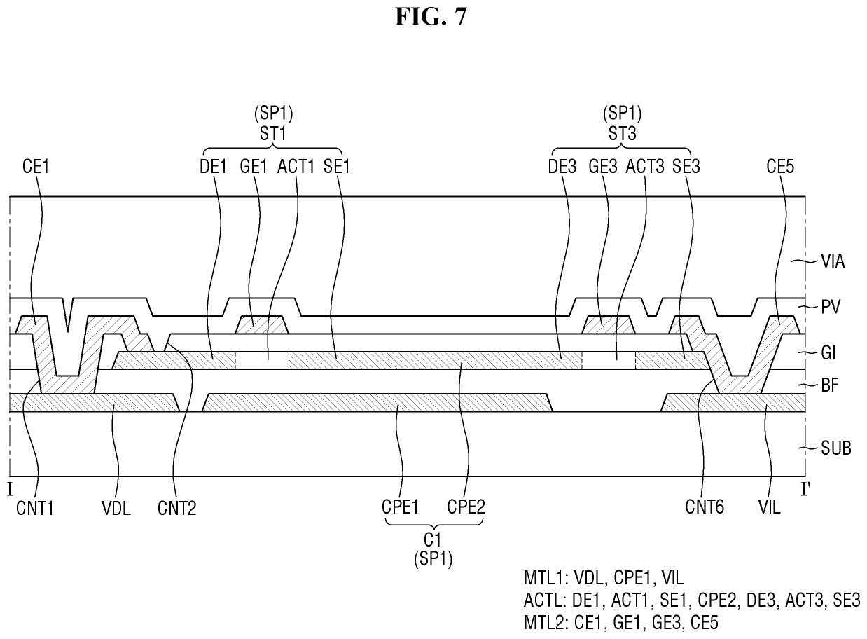

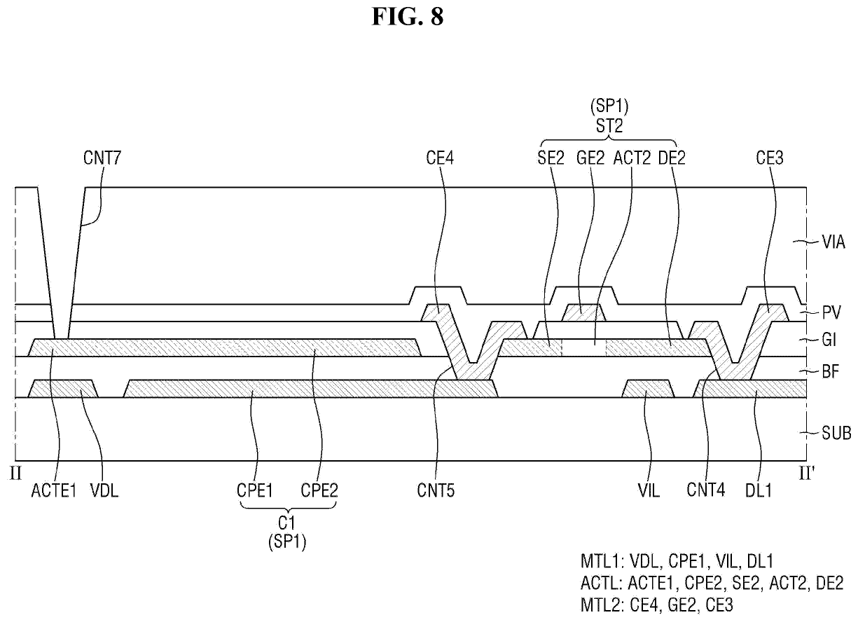

FIGS. 5 and 6 are schematic plan views of a portion of the display area in the display device according to the embodiment. FIG. 7 is a schematic cross-sectional view taken along line I-I′ of FIGS. 5 and 6. FIG. 8 is a schematic cross-sectional view taken along line II-IF of FIGS. 5 and 6.

Referring to FIGS. 5 to 8, the display area DA may include pixels SP, a first voltage line VDL, a horizontal voltage line HVDL, an initialization voltage line VIL, an n^{th} vertical gate line VGLn, an n^{th} horizontal gate line HGLn, an auxiliary gate line BGL, data lines DL, a vertical voltage line VVSL, and a second voltage line VSL.

The pixels SP may include first to third pixels SP1 to SP3. A pixel circuit of the first pixel SP1, a pixel circuit of the third pixel SP3, and a pixel circuit of the second pixel SP2 may be arranged in the direction opposite to the second direction (e.g., Y-axis direction), but the order of the pixel circuits is not limited thereto.

The first voltage line VDL may be disposed in (e.g., included in) a first metal layer MTL1 on a substrate SUB. The first voltage line VDL may be disposed on a left side of the pixel circuits of the first to third pixels SP1 to SP3. The first voltage line VDL may overlap a first connection electrode CE1 and a sixth connection electrode CE6 of a second metal layer MTL2 in a thickness direction (e.g., Z-axis direction). The first voltage line VDL may be connected to the first connection electrode CE1 through a first contact hole CNT1. The first connection electrode CE1 may be connected to a drain electrode DE1 of a first transistor ST1 of the first pixel SP1 through a second contact hole CNT2. The first voltage line VDL may be connected to the sixth connection electrode CE6 through eighth contact holes CNT8. The sixth connection electrode CE6 may be connected to a drain electrode DE1 of a first transistor ST1 of the second pixel SP2 through a ninth contact hole CNT9 and may be connected to a drain electrode DE1 of a first transistor ST1 of the third pixel SP3 through a fifteenth contact hole CNT15. Therefore, the first voltage line VDL may supply a driving voltage to the first to third pixels SP1 to SP3 through the first and sixth connection electrodes CE1 and CE6.

The horizontal voltage line HVDL may be disposed in (e.g., included in) the second metal layer MTL2. The second metal layer MTL2 may be disposed on a gate insulating layer GI covering an active layer ACTL. The horizontal voltage line HVDL may be disposed above the n^{th} horizontal gate line HGLn. The horizontal voltage line HVDL may be connected to the first voltage line VDL through a twenty-third contact hole CNT23 to receive a driving voltage. The horizontal voltage line HVDL may supply a driving voltage or a high potential voltage to an alignment electrode of a third metal layer.

The initialization voltage line VIL may be disposed in (e.g., included in) the first metal layer MTL1. The initialization voltage line VIL may be disposed on a right side of the auxiliary gate line BGL. A fifth connection electrode CE5 of the second metal layer MTL2 may electrically connect the initialization voltage line VIL to a source electrode SE3 of a third transistor ST3 of the first pixel SP1 through a sixth contact hole CNT6. A tenth connection electrode CE10 of the second metal layer MTL2 may electrically connect the initialization voltage line VIL to a source electrode SE3 of a third transistor ST3 of the second pixel SP2 and a source electrode SE3 of a third transistor ST3 of the third pixel SP3 through a thirteenth contact hole CNT13. The source electrode SE3 of the third transistor ST3 of the second pixel SP2 and the source electrode SE3 of the third transistor ST3 of the third pixel SP3 may be integral with each other, but the disclosure is not limited thereto. Therefore, the initialization voltage line VIL may supply an initialization voltage to the third transistor ST3 of each of the first to third pixels SP1 to SP3 and may receive a sensing signal from the third transistor ST3.

Multiple vertical gate lines VGL may be disposed in (e.g., included in) the first metal layer MTL1. The (n−1)^{th} and n^{th} vertical gate lines VGLn−1 and VGLn may be disposed on a left side of the first voltage line VDL. The (n−1)^{th} vertical gate line VGLn−1 may overlap auxiliary electrodes AUE of the second metal layer MTL2 in the thickness direction (e.g., Z-axis direction) and may be connected to the auxiliary electrodes AUE through twenty-first contact holes CNT21. Therefore, the (n−1)^{th} vertical gate line VGLn−1 connected to the auxiliary electrodes AUE may reduce line resistance.

The n^{th} vertical gate line VGLn may be connected to the n^{th} horizontal gate line HGLn of the second metal layer MTL2 through a contact portion MDC. The n^{th} vertical gate line VGLn may supply a gate signal to the n^{th} horizontal gate line HGLn. The n^{th} vertical gate line VGLn may overlap auxiliary electrodes AUE of the second metal layer MTL2 in the thickness direction (e.g., Z-axis direction) and may be connected to the auxiliary electrodes AUE through twenty-second contact holes CNT22. Therefore, the n^{th} vertical gate line VGLn connected to the auxiliary electrodes AUE may reduce line resistance.

The n^{th} horizontal gate line HGLn may be disposed in (e.g., included in) the second metal layer MTL2. The n^{th} horizontal gate line HGLn may be disposed above the pixel circuit of the first pixel SP1. The n^{th} horizontal gate line HGLn may be connected to the n^{th} vertical gate line VGLn disposed in (e.g., included in) the first metal layer MTL1 through the contact portion MDC. The n^{th} horizontal gate line HGLn may supply a gate signal received from the n^{th} vertical gate line VGLn to the auxiliary gate line BGL.

The auxiliary gate line BGL may be disposed in (e.g., included in) the second metal layer MTL2. The auxiliary gate line BGL may protrude from the n^{th} horizontal gate line HGLn in the direction opposite to the second direction (e.g., Y-axis direction). The auxiliary gate line BGL and the n^{th} horizontal gate line HGLn may be integral with each other, but the disclosure is not limited thereto. The auxiliary gate line BGL may be disposed on a right side of the pixel circuits of the first to third pixels SP1 to SP3. The auxiliary gate line BGL may supply a gate signal received from the n^{th} horizontal gate line HGLn to the second and third transistors ST2 and ST3 of each of the first to third pixels SP1 to SP3.

A first data line DL1 may be disposed in (e.g., included in) the first metal layer MTL1. The first data line DL1 may be disposed on a right side of the initialization voltage line VIL. A third connection electrode CE3 of the second metal layer MTL2 may electrically connect the first data line DL1 to a drain electrode DE2 of the second transistor ST2 of the first pixel SP1 through a fourth contact hole CNT4. The first data line DL1 may supply a data voltage to the second transistor ST2 of the first pixel SP1.

A second data line DL2 may be disposed in (e.g., included in) the first metal layer MTL1. The second data line DL2 may be disposed on a right side of the first data line DL1. An eighth connection electrode CE8 of the second metal layer MTL2 may electrically connect the second data line DL2 to a drain electrode DE2 of the second transistor ST2 of the second pixel SP2 through an eleventh contact hole CNT11. The second data line DL2 may supply a data voltage to the second transistor ST2 of the second pixel SP2.

A third data line DL3 may be disposed in (e.g., included in) the first metal layer MTL1. The third data line DL3 may be disposed on a right side of the second data line DL2. A twelfth connection electrode CE12 of the second metal layer MTL2 may electrically connect the third data line DL3 to a drain electrode DE2 of the second transistor ST2 of the third pixel SP3 through a seventeenth contact hole CNT17. The third data line DL3 may supply a data voltage to the second transistor ST2 of the third pixel SP3.

The vertical voltage line VVSL may be disposed in (e.g., included in) the first metal layer MTL1. The vertical voltage line VVSL may be disposed on a left side of the (n−1)^{th} vertical gate line VGLn−1. The vertical voltage line VVSL may be connected to the second voltage line VSL of the second metal layer MTL2 through a twenty-fourth contact hole CNT24. The vertical voltage line VVSL may supply a low potential voltage to the second voltage line VSL. The vertical voltage line VVSL may overlap an auxiliary electrode AUE of the second metal layer MTL2 in the thickness direction (e.g., Z-axis direction) and may be connected to the auxiliary electrode AUE through twentieth contact holes CNT20. Therefore, the vertical voltage line VVSL connected to the auxiliary electrode AUE may reduce line resistance.

The second voltage line VSL may be disposed in (e.g., included in) the second metal layer MTL2. The second voltage line VSL may be disposed below the pixel circuit of the second pixel SP2. The second voltage line VSL may supply a low potential voltage received from the vertical voltage line VVSL to a second electrode of each of the first to third pixels SP1 to SP3. For example, the second voltage line VSL may be connected to the second electrode of the first pixel SP1 through a twenty-sixth contact hole CNT26. The second voltage line VSL may be connected to the second electrode of the second pixel SP2 through a twenty-seventh contact hole CNT27. The second voltage line VSL may be connected to the second electrode of the third pixel SP3 through a twenty-eighth contact hole CNT28. The second electrode of each of the first to third pixels SP1 to SP3 may be disposed in (e.g., included in) the third metal layer, and the twenty-sixth to twenty-eighth contact holes CNT26 to CNT28 may penetrate a via layer VIA and a passivation layer PV. The passivation layer PV may be disposed on the second metal layer MTL2 and the gate insulating layer GI, and the via layer VIA may be disposed on the passivation layer PV.

The pixel circuit of the first pixel SP1 may include the first to third transistors ST1 to ST3. The first transistor ST1 of the first pixel SP1 may include an active region ACT1, a gate electrode GE1, the drain electrode DE1, and a source electrode SE1. The active region ACT1 of the first transistor ST1 may be disposed in (e.g., included in) the active layer ACTL and may overlap the gate electrode GE1 of the first transistor ST1 in the thickness direction (e.g., Z-axis direction). The active layer ACTL may be disposed on a buffer layer BF covering the first metal layer MTL1.

The gate electrode GE1 of the first transistor ST1 may be disposed in (e.g., included in) the second metal layer MTL2. The gate electrode GE1 of the first transistor ST1 may be a portion of a second connection electrode CE2. The second connection electrode CE2 may be connected to a first capacitor electrode CPE1 of a first capacitor C1 of the first pixel SP1 disposed in (e.g., included in) the first metal layer MTL1 through a third contact hole CNT3.

The active layer ACTL may be heat-treated, and the drain electrode DE1 and the source electrode SE1 of the first transistor ST1 (e.g., the first transistor ST1 of the first pixel SP1) may be formed into conductors (or may have electrical conductivity). The drain electrode DE1 and the source electrode SE1 of the first transistor ST1 may be formed into N-type semiconductors, but the disclosure is not limited thereto. The first connection electrode CE1 may electrically connect the first voltage line VDL to the drain electrode DE1 of the first transistor ST1 through the first contact hole CNT1. The drain electrode DE1 of the first transistor ST1 may receive a driving voltage from the first voltage line VDL.

The source electrode SE1 of the first transistor ST1 and a second capacitor electrode CPE2 of the first capacitor C1 may be integral with each other. Thus, the display device 10 may not include a separate contact hole through which the source electrode SE1 of the first transistor ST1 and the second capacitor electrode CPE2 of the first capacitor C1 contact each other. Therefore, the area of the first capacitor C1 may be secured, and the capacitance of the first capacitor C1 may be increased.

The first capacitor C1 may be formed between the first capacitor electrode CPE1 of the first metal layer MTL1 and the second capacitor electrode CPE2 of the active layer ACTL. The second capacitor electrode CPE2 may be disposed on the first capacitor electrode CPE1. Thus, coupling capacitance between the first capacitor electrode CPE1 (e.g., the first capacitor electrode CPE1 of the first capacitor C1 of the first pixel SP1) and a second electrode of the third metal layer may be minimized, and horizontal crosstalk may be prevented. Therefore, image quality may be improved.

The second capacitor electrode CPE2 of the first pixel SP1 may include a first active extension portion ACTE1 of the active layer ACTL. The first active extension portion ACTE1 and the second capacitor electrode CPE2 of the first pixel SP1 may be integral with each other. The first active extension portion ACTE1 may extend to the left (or in a left direction) from the second capacitor electrode CPE2. The first active extension portion ACTE1 may be connected to a first electrode or a first contact electrode of the first pixel SP1 through a seventh contact hole CNT7. The first electrode of the first pixel SP1 may be disposed in (e.g., included in) the third metal layer, and the first contact electrode of the first pixel SP1 may be disposed in (e.g., included in) a fourth metal layer. The seventh contact hole CNT7 may penetrate the via layer VIA, the passivation layer PV, and the gate insulating layer GI.

The second transistor ST2 of the first pixel SP1 may include an active region ACT2, a gate electrode GE2, the drain electrode DE2, and a source electrode SE2. The active region ACT2 of the second transistor ST2 may be disposed in (e.g., included in) the active layer ACTL and may overlap the gate electrode GE2 of the second transistor ST2 in the thickness direction (e.g., Z-axis direction).

The gate electrode GE2 of the second transistor ST2 may be disposed in (e.g., included in) the second metal layer MTL2. The gate electrode GE2 of the second transistor ST2 may be a portion of the auxiliary gate line BGL.

The active layer ACTL may be heat-treated, and the drain electrode DE2 and the source electrode SE2 of the second transistor ST2 (e.g., the second transistor ST2 of the first pixel SP1) may be formed into conductors (or may have electrical conductivity). The drain electrode DE2 of the second transistor ST2 may be electrically connected to the first data line DL1 through the third connection electrode CE3. The drain electrode DE2 of the second transistor ST2 may receive a data voltage of the first pixel SP1 from the first data line DL1.

The source electrode SE2 of the second transistor ST2 may be connected to a fourth connection electrode CE4 of the second metal layer MTL2 through a fifth contact hole CNT5. The fourth connection electrode CE4 may electrically connect the source electrode SE2 of the second transistor ST2 and the first capacitor electrode CPE1 of the first metal layer MTL1 through the fifth contact hole CNT5.

The third transistor ST3 of the first pixel SP1 may include an active region ACT3, a gate electrode GE3, a drain electrode DE3, and the source electrode SE3. The active region ACT3 of the third transistor ST3 may be disposed in (e.g., included in) the active layer ACTL and may overlap the gate electrode GE3 of the third transistor ST3 in the thickness direction (e.g., Z-axis direction).

The gate electrode GE3 of the third transistor ST3 may be disposed in (e.g., included in) the second metal layer MTL2. The gate electrode GE3 of the third transistor ST3 may be a portion of the auxiliary gate line BGL.

The active layer ACTL may be heat-treated, and the drain electrode DE3 and the source electrode SE3 of the third transistor ST3 (e.g., the third transistor ST3 of the first pixel SP1) may be formed into conductors (or may have electrical conductivity). For example, the heat-treating of the active layer ACTL of the first pixel SP1 may simultaneously form multiple drain electrodes (e.g., the drain electrodes DE1 to DE3 of the first to third transistors ST1 to ST3) and multiple source electrodes (e.g., the source electrodes SE1 to SE3 of the first to third transistors ST1 to ST3). The drain electrode DE3 of the third transistor ST3 and the second capacitor electrode CPE2 of the first capacitor C1 may be integral with each other. Thus, the display device 10 may not include a separate contact hole through which the drain electrode DE3 of the third transistor ST3 and the second capacitor electrode CPE2 of the first capacitor C1 contact each other. Therefore, the area of the first capacitor C1 may be secured, and the capacitance of the first capacitor C1 may be increased.

The source electrode SE3 of the third transistor ST3 may be connected to the fifth connection electrode CE5 of the second metal layer MTL2 through the sixth contact hole CNT6. The fifth connection electrode CE5 may electrically connect the source electrode SE3 of the third transistor ST3 and the initialization voltage line VIL through the sixth contact hole CNT6. The source electrode SE3 of the third transistor ST3 may receive an initialization voltage from the initialization voltage line VIL. The source electrode SE3 of the third transistor ST3 may supply a sensing signal to the initialization voltage line VIL.

The pixel circuit of the second pixel SP2 may include the first to third transistors ST1 to ST3. The first transistor ST1 of the second pixel SP2 may include an active region ACT1, a gate electrode GE1, the drain electrode DE1, and a source electrode SE1. The active region ACT1 of the first transistor ST1 may be disposed in (e.g., included in) the active layer ACTL and may overlap the gate electrode GE1 of the first transistor ST1 in the thickness direction (e.g., Z-axis direction).

The gate electrode GE1 of the first transistor ST1 may be disposed in (e.g., included in) the second metal layer MTL2. The gate electrode GE1 of the first transistor ST1 may be a portion of a seventh connection electrode CE7. The seventh connection electrode CE7 may be connected to a first capacitor electrode CPE1 of a first capacitor C1 of the second pixel SP2 disposed in (e.g., included in) the first metal layer MTL1 through a tenth contact hole CNT10.

The active layer ACTL may be heat-treated, and the drain electrode DE1 and the source electrode SE1 of the first transistor ST1 (e.g., the first transistor ST1 of the second pixel SP2) may be formed into conductors (or may have electrical conductivity). The drain electrode DE1 and the source electrode SE1 of the first transistor ST1 may be formed into N-type semiconductors, but the disclosure is not limited thereto. The sixth connection electrode CE6 may electrically connect the first voltage line VDL to the drain electrode DE1 of the first transistor ST1 through the ninth contact hole CNT9. The drain electrode DE1 of the first transistor ST1 may receive a driving voltage from the first voltage line VDL.

The source electrode SE1 of the first transistor ST1 and a second capacitor electrode CPE2 of the first capacitor C1 may be integral with each other. Thus, the display device 10 may not include a separate contact hole through which the source electrode SE1 of the first transistor ST1 and the second capacitor electrode CPE2 of the first capacitor C1 contact each other. Therefore, the area of the first capacitor C1 may be secured, and the capacitance of the first capacitor C1 may be increased.

The first capacitor C1 may be formed between the first capacitor electrode CPE1 of the first metal layer MTL1 and the second capacitor electrode CPE2 of the active layer ACTL. The second capacitor electrode CPE2 may be disposed on the first capacitor electrode CPE1. Thus, coupling capacitance between the first capacitor electrode CPE1 (e.g., the first capacitor electrode CPE1 of the first capacitor C1 of the second pixel SP2) and the second electrode of the third metal layer may be minimized and horizontal crosstalk may be prevented. Therefore, image quality may be improved.

The second capacitor electrode CPE2 of the second pixel SP2 may include a second active extension portion ACTE2 of the active layer ACTL. The second active extension portion ACTE2 and the second capacitor electrode CPE2 of the second pixel SP2 may be integral with each other. The second active extension portion ACTE2 may extend to the right (or in a right direction) from the second capacitor electrode CPE2. The second active extension portion ACTE2 may be connected to a first electrode or a first contact electrode of the second pixel SP2 through a fourteenth contact hole CNT14. The first electrode of the second pixel SP2 may be disposed in (e.g., included in) the third metal layer, and the first contact electrode of the second pixel SP2 may be disposed in (e.g., included in) the fourth metal layer. The fourteenth contact hole CNT14 may penetrate the via layer VIA, the passivation layer PV, and the gate insulating layer GI.

The second transistor ST2 of the second pixel SP2 may include an active region ACT2, a gate electrode GE2, the drain electrode DE2, and a source electrode SE2. The active region ACT2 of the second transistor ST2 may be disposed in (e.g., included in) the active layer ACTL and may overlap the gate electrode GE2 of the second transistor ST2 in the thickness direction (e.g., Z-axis direction).

The gate electrode GE2 of the second transistor ST2 may be disposed in (e.g., included in) the second metal layer MTL2. The gate electrode GE2 of the second transistor ST2 may be a portion of the auxiliary gate line BGL.

The active layer ACTL may be heat-treated, and the drain electrode DE2 and the source electrode SE2 of the second transistor ST2 (e.g., the second transistor ST2 of the second pixel SP2) may be formed into conductors (or may have electrical conductivity). The drain electrode DE2 of the second transistor ST2 may be electrically connected to a second data line DL2 through the eighth connection electrode CE8. The drain electrode DE2 of the second transistor ST2 may receive a data voltage of the second pixel SP2 from the second data line DL2.

The source electrode SE2 of the second transistor ST2 may be connected to a ninth connection electrode CE9 of the second metal layer MTL2 through a twelfth contact hole CNT12. The ninth connection electrode CE9 may electrically connect the source electrode SE2 of the second transistor ST2 and the first capacitor electrode CPE1 of the first metal layer MTL1 through the twelfth contact hole CNT12.

The third transistor ST3 of the second pixel SP2 may include an active region ACT3, a gate electrode GE3, the drain electrode DE3, and the source electrode SE3. The active region ACT3 of the third transistor ST3 may be disposed in (e.g., included in) the active layer ACTL and may overlap the gate electrode GE3 of the third transistor ST3 in the thickness direction (e.g., Z-axis direction).

The gate electrode GE3 of the third transistor ST3 may be disposed in (e.g., included in) the second metal layer MTL2. The gate electrode GE3 of the third transistor ST3 may be a portion of the auxiliary gate line BGL.

The active layer ACTL may be heat-treated, and the drain electrode DE3 and the source electrode SE3 of the third transistor ST3 (e.g., the third transistor ST3 of the second pixel SP2) may be formed into conductors (or may have electrical conductivity). For example, the heat-treating of the active layer ACTL of the second pixel SP2 may simultaneously form multiple drain electrodes (e.g., the drain electrodes DE1 to DE3 of the first to third transistors ST1 to ST3) and multiple source electrodes (e.g., the source electrodes SE1 to SE3 of the first to third transistors ST1 to ST3). The drain electrode DE3 of the third transistor ST3 and the second capacitor electrode CPE2 of the first capacitor C1 may be integral with each other. Thus, the display device 10 may not include a separate contact hole through which the drain electrode DE3 of the third transistor ST3 and the second capacitor electrode CPE2 of the first capacitor C1 contact each other. Therefore, the area of the first capacitor C1 may be secured, and the capacitance of the first capacitor C1 may be increased.

The source electrode SE3 of the third transistor ST3 may be connected to the tenth connection electrode CE10 of the second metal layer MTL2 through the thirteenth contact hole CNT13. The tenth connection electrode CE10 may electrically connect the source electrode SE3 of the third transistor ST3 and the initialization voltage line VIL through the thirteenth contact hole CNT13. The source electrode SE3 of the third transistor ST3 may receive an initialization voltage from the initialization voltage line VIL. The source electrode SE3 of the third transistor ST3 may supply a sensing signal to the initialization voltage line VIL.

The pixel circuit of the third pixel SP3 may include the first to third transistors ST1 to ST3. The first transistor ST1 of the third pixel SP3 may include an active region ACT1, a gate electrode GE1, the drain electrode DE1, and a source electrode SE1. The active region ACT1 of the first transistor ST1 may be disposed in (e.g., included in) the active layer ACTL and may overlap the gate electrode GE1 of the first transistor ST1 in the thickness direction (e.g., Z-axis direction).

The gate electrode GE1 of the first transistor ST1 may be disposed in (e.g., included in) the second metal layer MTL2. The gate electrode GE1 of the first transistor ST1 may be a portion of an eleventh connection electrode CE11. The eleventh connection electrode CE11 may be connected to the first capacitor electrode CPE1 of a first capacitor C1 of the third pixel SP3 disposed in (e.g., included in) the first metal layer MTL1 through a sixteenth contact hole CNT16.

The active layer ACTL may be heat-treated, and the drain electrode DE1 and the source electrode SE1 of the first transistor ST1 (the first transistor ST1 of the third pixel SP3) may be formed into conductors (or may have electrically conductivity). The drain electrode DE1 and the source electrode SE1 of the first transistor ST1 may be formed into N-type semiconductors, but the disclosure is not limited thereto. The sixth connection electrode CE6 may electrically connect the first voltage line VDL to the drain electrode DE1 of the first transistor ST1 through the fifteenth contact hole CNT15. The drain electrode DE1 of the first transistor ST1 may receive a driving voltage from the first voltage line VDL.

The source electrode SE1 of the first transistor ST1 and a second capacitor electrode CPE2 of the first capacitor C1 of the third pixel SP3 may be integral with each other. Thus, the display device 10 may not include a separate contact hole through which the source electrode SE1 of the first transistor ST1 and the second capacitor electrode CPE2 of the first capacitor C1 contact each other. Therefore, the area of the first capacitor C1 may be secured, and the capacitance of the first capacitor C1 may be increased.

The first capacitor C1 of the third pixel SP3 may be formed between the first capacitor electrode CPE1 of the first metal layer MTL1 and the second capacitor electrode CPE2 of the active layer ACTL. The second capacitor electrode CPE2 may be disposed on the first capacitor electrode CPE1. Thus, coupling capacitance between the first capacitor electrode CPE1 (e.g., the first capacitor electrode CPE1 of the first capacitor C1 of the third pixel SP3) and the second electrode of the third metal layer may be minimized, and horizontal crosstalk may be prevented. Therefore, image quality may be improved.

The second capacitor electrode CPE2 of the third pixel SP3 may include a third active extension portion ACTE3 of the active layer ACTL. The third active extension portion ACTE3 and the second capacitor electrode CPE2 of the third pixel SP3 may be integral with each other. The third active extension portion ACTE3 may extend to the left (or in the left direction) from the second capacitor electrode CPE2 and may be bent to extend downward. The third active extension portion ACTE3 may intersect (or cross) the first voltage line VDL and the (n−1)^{th} and n^{th} vertical gate lines VGLn−1 and VGLn and may overlap the vertical voltage line VVSL in a plan view (or in the thickness direction or Z-axis direction). The third active extension portion ACTE3 may be connected to a first electrode or a first contact electrode of the third pixel SP3 through a nineteenth contact hole CNT19. The first electrode of the third pixel SP3 may be disposed in (e.g., included in) the third metal layer, and the first contact electrode of the third pixel SP3 may be disposed in (e.g., included in) the fourth metal layer. The nineteenth contact hole CNT19 may penetrate the via layer VIA, the passivation layer PV, and the gate insulating layer GI.

The second transistor ST2 of the third pixel SP3 may include an active region ACT2, a gate electrode GE2, the drain electrode DE2, and a source electrode SE2. The active region ACT2 of the second transistor ST2 may be disposed in (e.g., included in) the active layer ACTL and may overlap the gate electrode GE2 of the second transistor ST2 in the thickness direction (e.g., Z-axis direction).

The gate electrode GE2 of the second transistor ST2 may be disposed in (e.g., included in) the second metal layer MTL2. The gate electrode GE2 of the second transistor ST2 may be a portion of the auxiliary gate line BGL.

The active layer ACTL may be heat-treated, and the drain electrode DE2 and the source electrode SE2 of the second transistor ST2 (e.g., the second transistor ST2 of the third pixel SP3) may be formed into conductors (or may have electrical conductivity). The drain electrode DE2 of the second transistor ST2 may be electrically connected to a third data line DL3 through the twelfth connection electrode CE12. The drain electrode DE2 of the second transistor ST2 may receive a data voltage of the third pixel SP3 from the third data line DL3.

The source electrode SE2 of the second transistor ST2 may be connected to a thirteenth connection electrode CE13 of the second metal layer MTL2 through an eighteenth contact hole CNT18. The thirteenth connection electrode CE13 may electrically connect the source electrode SE2 of the second transistor ST2 and the first capacitor electrode CPE1 of the first metal layer MTL1 through the eighteenth contact hole CNT18.

The third transistor ST3 of the third pixel SP3 may include an active region ACT3, a gate electrode GE3, a drain electrode DE3, and the source electrode SE3. The active region ACT3 of the third transistor ST3 may be disposed in (e.g., included in) the active layer ACTL and may overlap the gate electrode GE3 of the third transistor ST3 in the thickness direction (e.g., Z-axis direction).

The gate electrode GE3 of the third transistor ST3 may be disposed in (e.g., included in) the second metal layer MTL2. The gate electrode GE3 of the third transistor ST3 may be a portion of the auxiliary gate line BGL.

The active layer ACTL may be heat-treated, and the drain electrode DE3 and the source electrode SE3 of the third transistor ST3 (e.g., the third transistor ST3 of the third pixel SP3) may be formed into conductors (or may have electrical conductivity). The heat-treating of the active layer ACTL of the third pixel SP3 may simultaneously form multiple drain electrodes (e.g., the drain electrodes DE1 to DE3 of the first to third transistors ST1 to ST3) and multiple source electrodes (e.g., the source electrodes SE1 to SE3 of the first to third transistors ST1 to ST3). For example, the heat-treating of the active layer ACTL may be simultaneously performed on multiple pixels (e.g., the first to third pixels SP1 to SP3). The drain electrode DE3 of the third transistor ST3 and the second capacitor electrode CPE2 of the first capacitor C1 may be integral with each other. Thus, the display device 10 may not include a separate contact hole through which the drain electrode DE3 of the third transistor ST3 and the second capacitor electrode CPE2 of the first capacitor C1 contact each other. Therefore, the area of the first capacitor C1 may be secured, and the capacitance of the first capacitor C1 may be increased.

The source electrode SE3 of the third transistor ST3 may be connected to the tenth connection electrode CE10 of the second metal layer MTL2 through the thirteenth contact hole CNT13. The tenth connection electrode CE10 may electrically connect the source electrode SE3 of the third transistor ST3 and the initialization voltage line VIL through the thirteenth contact hole CNT13. The source electrode SE3 of the third transistor ST3 may receive an initialization voltage from the initialization voltage line VIL. The source electrode SE3 of the third transistor ST3 may supply a sensing signal to the initialization voltage line VIL.

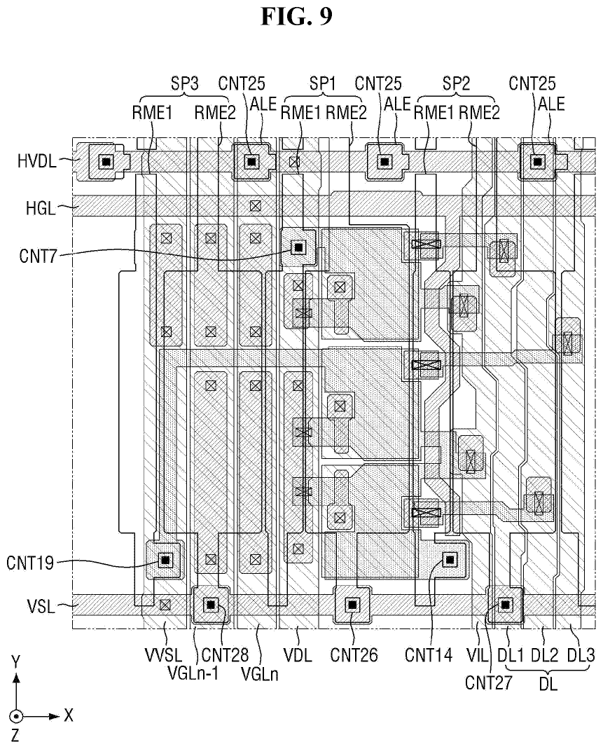

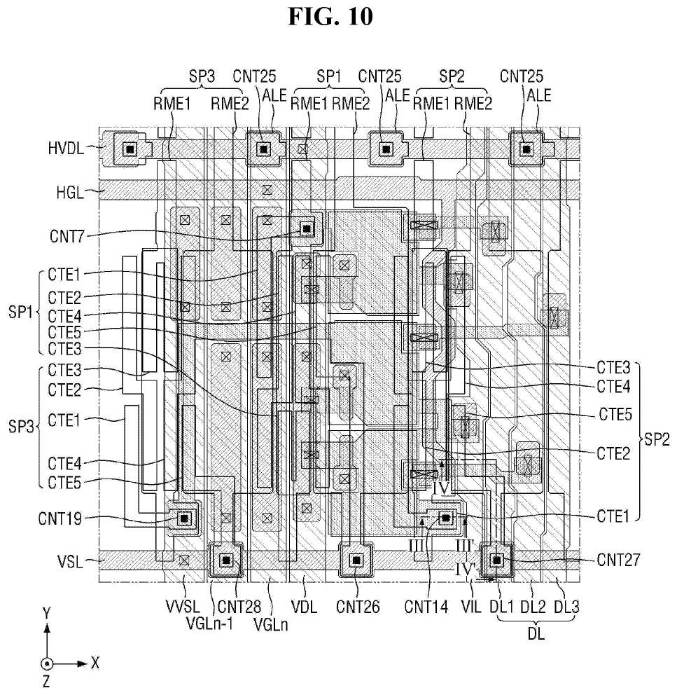

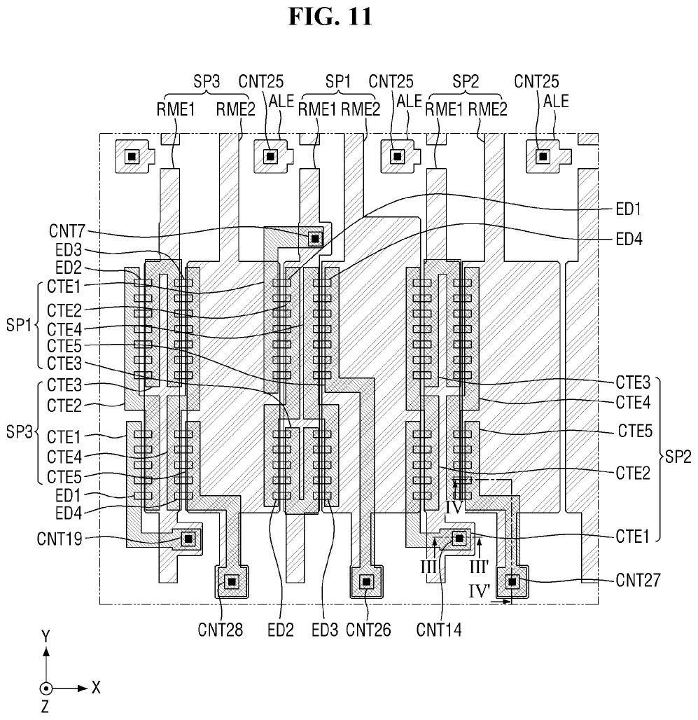

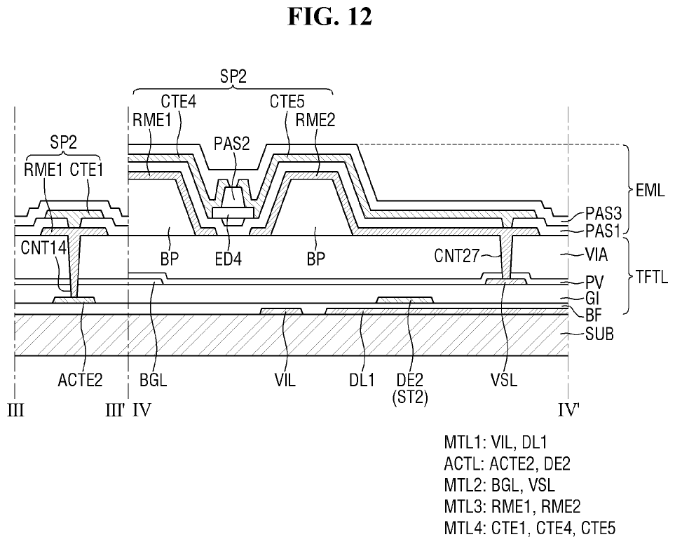

FIG. 9 is a schematic plan view illustrating the first metal layer, the active layer, the second metal layer, and a third metal layer in the display device according to the embodiment. FIG. 10 is a schematic plan view illustrating the first metal layer, the active layer, the second metal layer, the third metal layer, and a fourth metal layer in the display device according to the embodiment. In FIG. 9, the third metal layer MTL3 is added to FIGS. 5 and 6. In FIG. 10, the fourth metal layer MTL4 is added to FIG. 9. FIG. 11 is a schematic plan view illustrating the third metal layer, light emitting elements, and the fourth metal layer in the display device according to the embodiment. FIG. 12 is a schematic cross-sectional view taken along lines and IV-IV′ of FIGS. 10 and 11.

Referring to FIGS. 9 to 12, a light emitting element layer EML of the display device 10 may be disposed on a thin-film transistor layer TFTL. The light emitting element layer EML may include bank patterns BP, first and second electrodes RME1 and RME2, first to fourth light emitting elements ED1 to ED4, a first insulating layer PAS1, a second insulating layer PAS2, first to fifth contact electrodes CTE1 to CTE5, and a third insulating layer PAS3.

The bank patterns BP may be disposed on the via layer VIA and protrude in the upward direction (e.g., Z-axis direction). The bank patterns BP may have inclined side surfaces. Each of the first to fourth light emitting elements ED1 to ED4 may be disposed between the bank patterns BP spaced apart from each other. The bank patterns BP may be disposed as island-shaped patterns in the entire display area DA (e.g., refer to FIG. 2).

The first and second electrodes RME1 and RME2 of each of the first to third pixels SP1 to SP3 may be disposed in (e.g., included in) the third metal layer MTL3. The third metal layer MTL3 may be disposed on the via layer VIA and the bank patterns BP. The first and second electrodes RME1 and RME2 of each of the first to third pixels SP1 to SP3 may extend in the second direction (e.g., Y-axis direction). The first electrode RME1 of the first pixel SP1 may be disposed between the second electrode RME2 of the third pixel SP3 and the second electrode RME2 of the first pixel SP1. The first electrode RME1 of the second pixel SP2 may be disposed between the second electrode RME2 of the first pixel SP1 and the second electrode RME2 of the second pixel SP2. The first electrode RME1 of the third pixel SP3 may be disposed on a left side of the second electrode RME2 of the third pixel SP3.

Each of the first and second electrodes RME1 and RME2 may cover an upper surface and the inclined side surfaces of a bank pattern BP. Therefore, each of the first and second electrodes RME1 and RME2 may reflect light emitted from the first to fourth light emitting elements ED1 to ED4 in the upward direction (e.g., Z-axis direction). Thus, luminance of the display device 10 in the upward direction may be improved.

The first electrode RME1 may be separated on a row-by-row basis. The first and second electrodes RME1 and RME2 may be alignment electrodes that align the first to fourth light emitting elements ED1 to ED4 during a manufacturing process of the display device 10. The first electrode RME1 before being separated may be integrally formed with an alignment electrode ALE, and the alignment electrode ALE may be connected to the horizontal voltage line HVDL of the second metal layer MTL2 through a twenty-fifth contact hole CNT25. The alignment electrode ALE may receive a driving voltage or a high potential voltage from the horizontal voltage line HVDL and supply it to the first electrode RME1. Therefore, the first electrode RME1 may be separated from the alignment electrode ALE after the alignment process of light emitting elements ED is completed.

The first electrode RME1 of the first pixel SP1 may be connected to the first active extension portion ACTE1 of the active layer ACTL through the seventh contact hole CNT7. The first electrode RME1 may receive a driving current passing through the first transistor ST1. The first electrode RME1 may supply the driving current to the first light emitting elements ED1 of the first pixel SP1 through the first contact electrode CTE1.

The second electrode RME2 of the first pixel SP1 may be connected to the second voltage line VSL of the second metal layer MTL2 through the twenty-sixth contact hole CNT26. Therefore, the second electrode RME2 of the first pixel SP1 may receive a low potential voltage from the second voltage line VSL.

The first electrode RME1 of the second pixel SP2 may be connected to the second active extension portion ACTE2 of the active layer ACTL through the fourteenth contact hole CNT14. The first electrode RME1 may receive a driving current passing through the first transistor ST1. The first electrode RME1 may supply the driving current to the first light emitting elements ED1 of the second pixel SP2 through the first contact electrode CTE1.

The second electrode RME2 of the second pixel SP2 may be connected to the second voltage line VSL of the second metal layer MTL2 through the twenty-seventh contact hole CNT27. Therefore, the second electrode RME2 of the second pixel SP2 may receive a low potential voltage from the second voltage line VSL.

The first electrode RME1 of the third pixel SP3 may be connected to the third active extension portion ACTE3 of the active layer ACTL through the nineteenth contact hole CNT19. The first electrode RME1 may receive a driving current passing through the first transistor ST1. The first electrode RME1 may supply the driving current to the first light emitting elements ED1 of the third pixel SP3 through the first contact electrode CTE1.

The second electrode RME2 of the third pixel SP3 may be connected to the second voltage line VSL of the second metal layer MTL2 through the twenty-eighth contact hole CNT28. Therefore, the second electrode RME2 of the third pixel SP3 may receive a low potential voltage from the second voltage line VSL.

The first to fourth light emitting elements ED1 to ED4 may be aligned between the first electrode RME1 and the second electrode RME2. The first insulating layer PAS1 may cover the first and second electrodes RME1 and RME2. The first to fourth light emitting elements ED1 to ED4 may be insulated (e.g., electrically insulated) from the first and second electrodes RME1 and RME2 by the first insulating layer PAS1. Before the first electrode RME1 is separated from the alignment electrode ALE, during the manufacturing process of the display device 10, each of the first and second electrodes RME1 and RME2 may receive an alignment signal, and an electric field may be formed between the first and second electrodes RME1 and RME2. For example, the first to fourth light emitting elements ED1 to ED4 may be sprayed onto the first and second electrodes RME1 and RME2 through an inkjet printing process. The first to fourth light emitting elements ED1 to ED4 dispersed in ink may be aligned by a dielectrophoresis force applied by the electric field formed between the first and second electrodes RME1 and RME2. Therefore, the first to fourth light emitting elements ED1 to ED4 may be aligned along the second direction (e.g., Y-axis direction) between the first and second electrodes RME1 and RME2.

The first to fifth contact electrodes CTE1 to CTE5 of each of the first to third pixels SP1 to SP3 may be disposed in (e.g., included in) the fourth metal layer MTL4. The second insulating layer PAS2 may be disposed on a central portion of each light emitting element ED. The third insulating layer PAS3 may cover the first and second insulating layers PAS1 and PAS2 and the first to fifth contact electrodes CTE1 to CTE5. The second and third insulating layers PAS2 and PAS3 may insulate the first to fifth contact electrodes CTE1 to CTE5 from each other.

The first contact electrode CTE1 of the first pixel SP1 may be disposed on the second electrode RME2 of the third pixel SP3 and may be connected to the first electrode RME1 through a contact hole overlapping the seventh contact hole CNT7 in a plan view (e.g., in the thickness direction or Z-axis direction). The first contact electrode CTE1 may be connected between the first electrode RME1 and an end of each of the first light emitting elements ED1. The first contact electrode CTE1 may correspond to anodes of the first light emitting elements ED1, but the disclosure is not limited thereto.

The second contact electrode CTE2 (e.g., the second contact electrode CTE2 of the first pixel SP1) may be insulated from the first and second electrodes RME1 and RME2. A first portion of the second contact electrode CTE2 may be disposed on the first electrode RME1 of the first pixel SP1 and may extend in the second direction (e.g., Y-axis direction). A second portion of the second contact electrode CTE2 may be disposed on the second electrode RME2 of the third pixel SP3 and may extend in the second direction (e.g., Y-axis direction). The second portion of the second contact electrode CTE2 may extend from a lower side of the first portion of the second contact electrode CTE2.

The second contact electrode CTE2 may be connected between another end of each of the first light emitting elements ED1 and an end of each of the second light emitting elements ED2. The second contact electrode CTE2 may correspond to the third node N3 of FIG. 4. The second contact electrode CTE2 may correspond to cathodes of the first light emitting elements ED1, but the disclosure is not limited thereto. The second contact electrode CTE2 may correspond to anodes of the second light emitting elements ED2, but the disclosure is not limited thereto.

The third contact electrode CTE3 (e.g., the third contact electrode CTE3 of the first pixel SP1) may be insulated from the first and second electrodes RME1 and RME2. A first portion of the third contact electrode CTE3 may be disposed on the first electrode RME1 of the first pixel SP1 and may extend in the second direction (e.g., Y-axis direction). A second portion of the third contact electrode CTE3 may be disposed on the first electrode RME1 of the first pixel SP1 and may be disposed on a right side of the first portion of the third contact electrode CTE3.

The third contact electrode CTE3 may be connected between another end of each of the second light emitting elements ED2 and an end of each of the third light emitting elements ED3. The third contact electrode CTE3 may correspond to the fourth node N4 of FIG. 4. The third contact electrode CTE3 may correspond to cathodes of the second light emitting elements ED2, but the disclosure is not limited thereto. The third contact electrode CTE3 may correspond to anodes of the third light emitting elements ED3, but the disclosure is not limited thereto.

The fourth contact electrode CTE4 (e.g., the fourth contact electrode CTE4 of the first pixel SP1) may be insulated from the first and second electrodes RME1 and RME2. A first portion of the fourth contact electrode CTE4 may be disposed on the second electrode RME2 of the first pixel SP1 and may extend in the second direction (the Y-axis direction). A second portion of the fourth contact electrode CTE4 may be disposed on the first electrode RME1 of the first pixel SP1 and may extend in the second direction (e.g., Y-axis direction). The second portion of the fourth contact electrode CTE4 may extend from an upper side of the first portion of the fourth contact electrode CTE4.

The fourth contact electrode CTE4 may be connected between another end of each of the third light emitting elements ED3 and an end of each of the fourth light emitting elements ED4. The fourth contact electrode CTE4 may correspond to the fifth node N5 of FIG. 4. The fourth contact electrode CTE4 may correspond to cathodes of the third light emitting elements ED3, but the disclosure is not limited thereto. The fourth contact electrode CTE4 may correspond to anodes of the fourth light emitting elements ED4, but the disclosure is not limited thereto.

The fifth contact electrode CTE5 (e.g., the fifth contact electrode CTE5 of the first pixel SP1) may be insulated from the first and second electrodes RME1 and RME2. A first portion of the fifth contact electrode CTE5 may be disposed on the second electrode RME2 of the first pixel SP1 and may extend in the second direction (e.g., Y-axis direction). A second portion of the fifth contact electrode CTE5 may extend from the first portion to above the twenty-sixth contact hole CNT26. The second portion of the fifth contact electrode CTE5 may extend from a lower side of the first portion of the fifth contact electrode CTE5.

The fifth contact electrode CTE5 may be connected between another end of each of the fourth light emitting elements ED4 and the second electrode RME2. The fifth contact electrode CTE5 may correspond to cathodes of the fourth light emitting elements ED4, but the disclosure is not limited thereto. The fifth contact electrode CTE5 may receive a low potential voltage through the second electrode RME2.

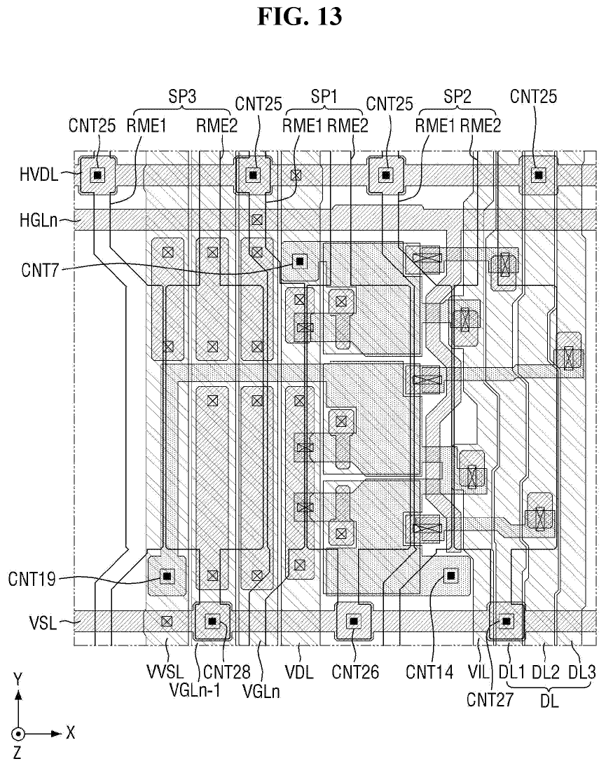

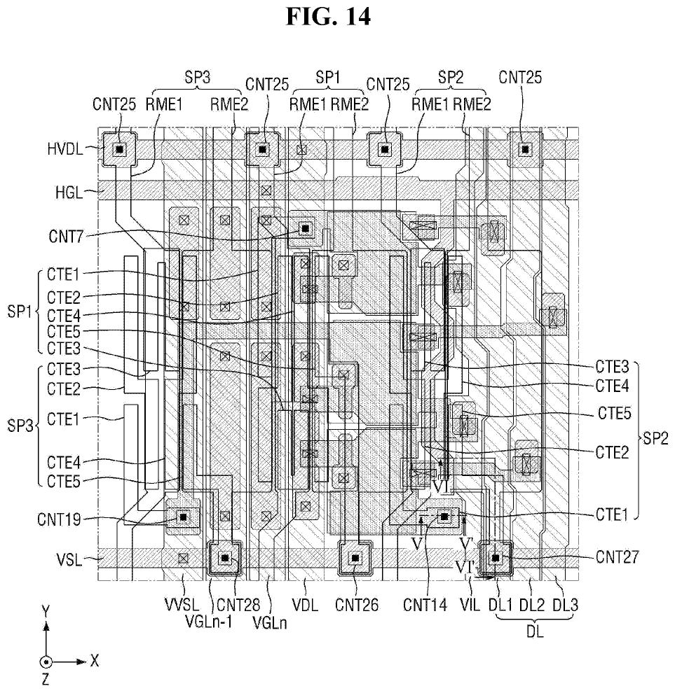

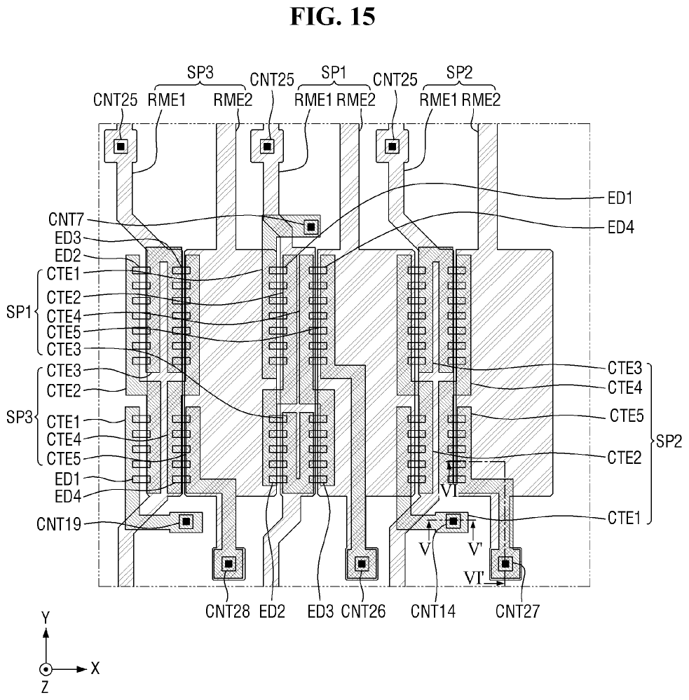

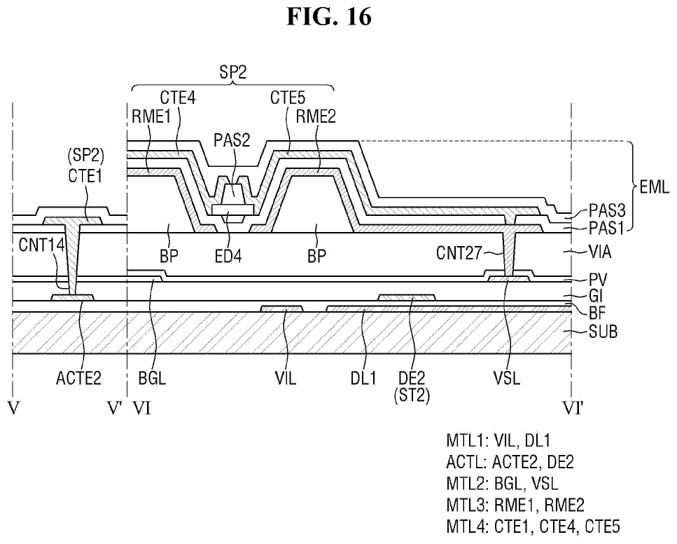

FIG. 13 is a schematic plan view illustrating a first metal layer, an active layer, a second metal layer, and a third metal layer in a display device according to an embodiment. FIG. 14 is a schematic plan view illustrating the first metal layer, the active layer, the second metal layer, the third metal layer, and a fourth metal layer in the display device according to the embodiment. In FIG. 13, the third metal layer MTL3 is added to FIGS. 5 and 6. In FIG. 14, the fourth metal layer MTL4 is added to FIG. 13. FIG. 15 is a schematic plan view illustrating the third metal layer, light emitting elements, and the fourth metal layer in the display device according to the embodiment. FIG. 16 is a schematic cross-sectional view taken along lines V-V′ and VI-VI′ of FIGS. 14 and 15. Thus, detailed description of the same constituent elements is omitted.

Referring to FIGS. 13 to 16, a light emitting element layer EML of the display device 10 may be disposed on a thin-film transistor layer TFTL. The light emitting element layer EML may include bank patterns BP, first and second electrodes RME1 and RME2, first to fourth light emitting elements ED1 to ED4, a first insulating layer PAS1, a second insulating layer PAS2, first to fifth contact electrodes CTE1 to CTE5, and a third insulating layer PAS3.

The first electrode RME1 of a first pixel SP1 may be connected to a horizontal voltage line HVDL of the second metal layer MTL2 through a twenty-fifth contact hole CNT25. The second electrode RME2 of the first pixel SP1 may be connected to a second voltage line VSL of the second metal layer MTL2 through a twenty-sixth contact hole CNT26. The first electrode RME1 may receive a driving voltage or a high potential voltage from the horizontal voltage line HVDL, and the second electrode RME2 may receive a low potential voltage from the second voltage line VSL. Therefore, the first and second electrodes RME1 and RME2 may be alignment electrodes that align the first to fourth light emitting elements ED1 to ED4 during a manufacturing process of the display device 10.

The first electrode RME1 of a second pixel SP2 may be connected to the horizontal voltage line HVDL of the second metal layer MTL2 through the twenty-fifth contact hole CNT25. The second electrode RME2 of the second pixel SP2 may be connected to the second voltage line VSL of the second metal layer MTL2 through a twenty-seventh contact hole CNT27.

The first electrode RME1 of a third pixel SP3 may be connected to the horizontal voltage line HVDL of the second metal layer MTL2 through the twenty-fifth contact hole CNT25. The second electrode RME2 of the third pixel SP3 may be connected to the second voltage line VSL of the second metal layer MTL2 through a twenty-eighth contact hole CNT28.

The first to fifth contact electrodes CTE1 to CTE5 of each of the first to third pixels SP1 to SP3 may be disposed in (e.g., included in) the fourth metal layer MTL4.

A first portion of the first contact electrode CTE1 of the first pixel SP1 may be inserted into a seventh contact hole CNT7 and connected to a first active extension portion ACTE1 of the active layer ACTL. A second portion of the first contact electrode CTE1 may be disposed on the second electrode RME2 of the third pixel SP3. The first contact electrode CTE1 may be connected between the first active extension portion ACTE1 and an end of each of the first light emitting elements ED1.

The second contact electrode CTE2 (e.g., the second contact electrode CTE2 of the first pixel SP1) may be connected between another end of each of the first light emitting elements ED1 and an end of each of the second light emitting elements ED2. The second contact electrode CTE2 may correspond to the third node N3 of FIG. 4. The third contact electrode CTE3 (e.g., the third contact electrode CTE3 of the first pixel SP1) may be connected between another end of each of the second light emitting elements ED2 and an end of each of the third light emitting elements ED3. The third contact electrode CTE3 may correspond to the fourth node N4 of FIG. 4. The fourth contact electrode CTE4 (e.g., the fourth contact electrode CTE4 of the first pixel SP1) may be connected between another end of each of the third light emitting elements ED3 and an end of each of the fourth light emitting elements ED4. The fourth contact electrode CTE4 may correspond to the fifth node N5 of FIG. 4. The fifth contact electrode CTE5 (e.g., the fifth contact electrode CTE5 of the first pixel SP1) may be connected between another end of each of the fourth light emitting elements ED4 and the second electrode RME2. The fifth contact electrode CTE5 may receive a low potential voltage through the second electrode RME2.

The first contact electrode CTE1 of the second pixel SP2 may be inserted into a fourteenth contact hole CNT14 and connected to a second active extension portion ACTE2 of the active layer ACTL. The first contact electrode CTE1 may be connected between the second active extension portion ACTE2 and the end of each of the first light emitting elements ED1. The fifth contact electrode CTE5 of the second pixel SP2 may receive a low potential voltage through the second electrode RME2.

The first contact electrode CTE1 of the third pixel SP3 may be inserted into a nineteenth contact hole CNT19 and connected to a third active extension portion ACTE3 of the active layer ACTL. The first contact electrode CTE1 may be connected between the third active extension portion ACTE3 and the end of each of the first light emitting elements ED1. The fifth contact electrode CTE5 of the third pixel SP3 may receive a low potential voltage through the second electrode RME2.

In a display device according to embodiments, a source electrode of a first transistor (or a drain electrode of a third transistor) and a second capacitor electrode may be integral with one another, and a separate contact hole may be omitted. Thus, the area of the first capacitor may be secured, and the capacitance of a first capacitor may be increased. For example, the area of the first capacitor may be increased, and the capacitance of the first capacitor may be increased. In the display device, the second capacitor electrode may be disposed on a first capacitor electrode. Thus, coupling capacitance between the first capacitor electrode and a second electrode may be minimized, and horizontal crosstalk may be prevented. Therefore, image quality may be improved.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first voltage line included in a first metal layer on a substrate and extending in a first direction;
a first transistor electrically connected to the first voltage line, the first transistor comprising:
a source electrode included in an active layer on the first metal layer; and
a gate electrode included in a second metal layer on the active layer; and
a first capacitor electrically connected between the gate electrode of the first transistor and the source electrode of the first transistor, the first capacitor comprising:
a first capacitor electrode included in the first metal layer and electrically connected to the gate electrode of the first transistor; and
a second capacitor electrode included in the active layer, the second capacitor electrode and the source electrode of the first transistor being integrally formed with each other.

2. The display device of claim 1, further comprising:
a first connection electrode included in the second metal layer and electrically connecting the first voltage line and a drain electrode of the first transistor.

3. The display device of claim 1, further comprising:
a second connection electrode included in the second metal layer, wherein
the second connection electrode and the gate electrode of the first transistor are integrally formed with each other, and
the second connection electrode is electrically connected to the first capacitor electrode.

4. The display device of claim 1, further comprising:
a data line included in the first metal layer and extending in the first direction; and
a second transistor electrically connecting the data line and the gate electrode of the first transistor.

5. The display device of claim 4, further comprising:
a third connection electrode included in the second metal layer and electrically connecting the data line and a drain electrode of the second transistor.

6. The display device of claim 4, further comprising:
a fourth connection electrode included in the second metal layer and electrically connecting the first capacitor electrode and a source electrode of the second transistor.

7. The display device of claim 1, further comprising:
an initialization voltage line included in the first metal layer and extending in the first direction; and
a third transistor electrically connecting the initialization voltage line and the source electrode of the first transistor.

8. The display device of claim 7, wherein a drain electrode of the third transistor and the second capacitor electrode are integral with each other.

9. The display device of claim 1, further comprising:
an active extension portion extending from the second capacitor electrode;
a first electrode included in a third metal layer on the second metal layer, extending in the first direction, and electrically connected to the active extension portion; and
a second electrode extending parallel to the first electrode included in the third metal layer.

10. The display device of claim 9, further comprising:
a light emitting element;
a second voltage line included in the second metal layer and extending in a second direction intersecting the first direction;
a first contact electrode included in a fourth metal layer on the third metal layer and electrically connecting the first electrode and the light emitting element; and
a second contact electrode included in the fourth metal layer and electrically connecting the light emitting element and the second voltage line.

11. The display device of claim 1, further comprising:
a horizontal voltage line included in the second metal layer, extending in a second direction intersecting the first direction, and electrically connected to the first voltage line;
a first electrode included in a third metal layer on the second metal layer, extending in the first direction, and electrically connected to the horizontal voltage line; and
a second electrode extending parallel to the first electrode included in the third metal layer.

12. The display device of claim 11, further comprising:
an active extension portion extending from the second capacitor electrode; and
a first contact electrode included in a fourth metal layer on the third metal layer and directly connected to the active extension portion.

13. The display device of claim 12, further comprising:
a light emitting element;
a second voltage line included in the second metal layer and extending in the second direction intersecting the first direction; and
a second contact electrode included in the fourth metal layer and electrically connecting the light emitting element and the second voltage line.

14. The display device of claim 1, further comprising:
a vertical gate line included in the first metal layer and extending in the first direction;
a horizontal gate line included in the second metal layer and extending in the second direction; and
an auxiliary gate line extending from the horizontal gate line in the first direction.

15. A display device comprising:
a first metal layer on a substrate;
an active layer on the first metal layer;
a second metal layer on the active layer;
a first transistor included in the active layer and the second metal layer; and
a first capacitor electrically connected between a gate electrode of the first transistor and a source electrode of the first transistor, the first capacitor comprising:
a first capacitor electrode included in the first metal layer and electrically connected to the gate electrode of the first transistor; and
a second capacitor electrode included in the active layer,
wherein the second capacitor electrode and the source electrode of the first transistor are integrally formed with each other.

16. The display device of claim 15, further comprising:
an active extension portion extending from the second capacitor electrode;
a first electrode included in a third metal layer on the second metal layer, extending in the first direction, and electrically connected to the active extension portion; and
a second electrode extending parallel to the first electrode included in the third metal layer.

17. The display device of claim 16, further comprising:
a light emitting element;
a second voltage line included in the second metal layer and extending in a second direction intersecting the first direction;
a first contact electrode included in a fourth metal layer on the third metal layer and electrically connecting the first electrode and the light emitting element; and
a second contact electrode included in the fourth metal layer and electrically connecting the light emitting element and the second voltage line.

18. The display device of claim 15, further comprising:
a horizontal voltage line included in the second metal layer, extending in a second direction intersecting the first direction, and electrically connected to the first voltage line;
a first electrode included in a third metal layer on the second metal layer, extending in the first direction, and electrically connected to the horizontal voltage line; and
a second electrode extending parallel to the first electrode included in the third metal layer.

19. The display device of claim 18, further comprising:
an active extension portion extending from the second capacitor electrode; and
a first contact electrode included in a fourth metal layer on the third metal layer and directly connected to the active extension portion.

20. The display device of claim 19, further comprising:
a light emitting element;
a second voltage line included in the second metal layer and extending in the second direction intersecting the first direction; and
a second contact electrode included in the fourth metal layer and electrically connecting the light emitting element and the second voltage line.
